(19) United States
(12) Patent Application Publication
(10) Pub. No.: US 2025/0357131 A1
(43) Pub. Date: Nov. 20, 2025

(54) Ionic Slurry for Electrochemical Mechanical Polishing

(71) Applicant: Wolfspeed, Inc., Durham, NC (US)

(72) Inventors: Simon Bubel, Carrboro, NC (US); Alexander Kevin Shveyd, Chapel Hill, NC (US); Dinusha Priyadarshani Karunaratne, Cary, NC (US)

(21) Appl. No.: 18/663,911

(22) Filed: May 14, 2024

(51) Int. Cl. H01L 21/306; B24B 37/04; C09G 1/02

(52) U.S. Cl. CPC H01L 21/30625; B24B 37/044; C09G 1/02

(57) ABSTRACT

A slurry for electrochemical mechanical polishing of semiconductor workpieces (e.g., silicon carbide semiconductor wafers) is provided. In one example embodiment, the slurry contains a solvent an abrasive particle, and an ionic compound. The ionic compound contains a cation and an anion. One or more of the cation or the anion is bonded to the abrasive particle, for instance, with a functional group or other bonding.

### FIELD

The present disclosure relates generally to semiconductor workpieces and semiconductor workpiece fabrication, and more particularly to polishing systems and methods for semiconductor workpieces, such as silicon carbide semiconductor wafers.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or may be learned from the description, or may be learned through practice of the embodiments.

In an aspect, the present disclosure provides an example slurry for use in an electrochemical mechanical polishing system. In some implementations, the example slurry includes a solvent. In some implementations, the example slurry includes an abrasive particle. In some implementations, the example slurry includes an ionic compound comprising a cation and an anion, wherein one or more of the cation or anion is bonded to the abrasive particle.

In an aspect, the present disclosure provides an example polishing system. In some implementations, the example polishing system includes a platen operable to rotate about an axis. In some implementations, the example polishing system includes a polishing pad on the platen. In some implementations, the example polishing system includes a bias source. In some implementations, the example polishing system includes a workpiece carrier operable to bring the semiconductor workpiece into contact with the polishing pad. In some implementations, the example polishing system includes a slurry comprising a solvent, an abrasive particle, and an ionic compound comprising a cation and an anion, wherein one or more of the cation or anion is bonded to the abrasive particle.

In an aspect, the present disclosure provides an example polishing system. In some implementations, the example polishing system includes a platen operable to rotate about an axis. In some implementations, the example polishing system includes a polishing pad on the platen. In some implementations, the example polishing system includes a bias source. In some implementations, the example polishing system includes a workpiece carrier operable to bring the semiconductor workpiece into contact with the polishing pad. In some implementations, the example polishing system includes a slurry comprising a solvent, a cationic abrasive particle, and an anion.

In an aspect, the present disclosure provides an example method. In some implementations, the example method includes providing the surface of the semiconductor workpiece on a polishing pad. In some implementations, the example method includes providing a slurry onto a surface of the polishing pad. In some implementations, the example method includes providing a bias between the semiconductor workpiece and the slurry, wherein the slurry includes a solvent and an ionic compound comprising a cation and an anion, wherein one or more of the cation or anion is bonded to an abrasive particle within the slurry.

In an aspect, the present disclosure provides an example method. In some implementations, the example method includes providing the surface of the semiconductor workpiece on a polishing pad. In some implementations, the example method includes providing a slurry onto a surface of the polishing pad. In some implementations, the example method includes providing a bias between the semiconductor workpiece and the slurry, wherein the slurry includes a solvent, a cationic abrasive particle, and an anion.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an example polishing system for a semiconductor workpiece according to example embodiments of the present disclosure;

FIG. 2A depicts a diagram of an abrasive particle, a cation, and an anion according to example embodiments of the present disclosure;

FIG. 2B depicts a diagram of an abrasive particle, a cation, and an anion according to example embodiments of the present disclosure;

FIG. 2C depicts a diagram of an abrasive particle, a cation, and an anion according to example embodiments of the present disclosure;

FIG. 2D depicts a diagram of abrasive particles, a cation, and an anion according to example embodiments of the present disclosure;

FIG. 2E depicts a diagram of abrasive particles, cations, and anions according to example embodiments of the present disclosure;

FIG. 2F depicts a diagram of an abrasive particle, a cation, and an anion according to example embodiments of the present disclosure;

FIG. 3A depicts a diagram of an abrasive particle, a cation, and an anion according to example embodiments of the present disclosure;

FIG. 3B depicts a diagram of an abrasive particle, a cation, and an anion according to example embodiments of the present disclosure;

FIG. 3C depicts a diagram of an abrasive particle, a cation, and an anion according to example embodiments of the present disclosure;

FIG. 3D depicts a diagram of abrasive particles, a cation, and an anion according to example embodiments of the present disclosure;

FIG. 3E depicts a diagram of abrasive particles, cations, and anions according to example embodiments of the present disclosure;

FIG. 3F depicts a diagram of an abrasive particle, a cation, and an anion according to example embodiments of the present disclosure;

FIG. 4 depicts a diagram of a slurry according to example embodiments of the present disclosure; and

FIG. 5 depicts a flow chart of an example method according to example embodiments of the present disclosure.

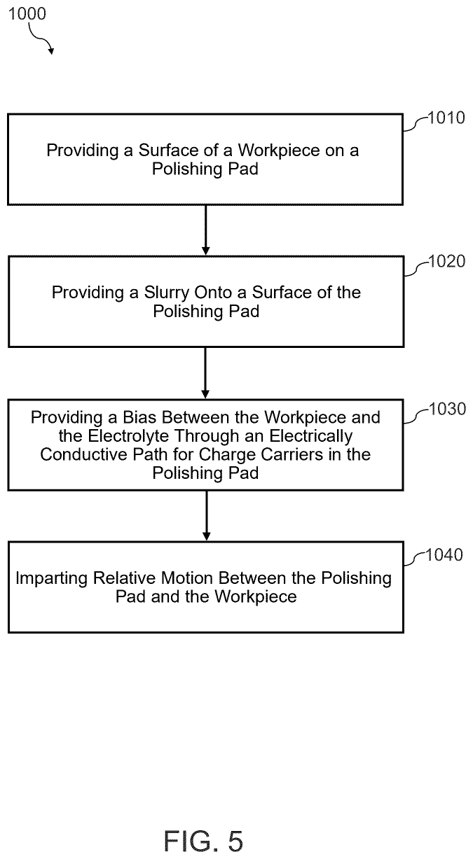

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that example embodiments of the present disclosure may be used with any semiconductor material, such as other wide bandgap semiconductor materials, without deviating from the scope of the present disclosure. Example wide bandgap semiconductor materials include silicon carbide and the Group III-nitrides.

Power semiconductor devices may be fabricated using epitaxial layers formed on a semiconductor workpiece, such as a silicon carbide semiconductor wafer. Power semiconductor device fabrication processes may include surface processing operations that are performed on the silicon carbide semiconductor wafer to prepare one or more surfaces of the silicon carbide semiconductor wafer for later processing steps, such as surface implantation, formation of epitaxial layers, metallization, etc. Example surface processing operations may include grinding operations, lapping operations, and polishing operations.

Aspects of the present disclosure are discussed with reference to a semiconductor workpiece that is a semiconductor wafer that includes silicon carbide (“silicon carbide semiconductor wafer”) for purposes of illustration and discussion. Those of ordinary skill in the art, using the disclosures provided herein, will understand that aspects of the present disclosure can be used with other semiconductor workpieces. Other semiconductor workpieces may include carrier substrates, ingots, boules, polycrystalline substrates, monocrystalline substrates, bulk crystalline material having a thickness of greater than about 1 mm, such as greater than about 5 mm, such as greater than about 10 mm, such as greater than about 20 mm, such as greater than about 50 mm, such as greater than about 100 mm, to 200 mm, etc.

In some examples, the semiconductor workpiece includes silicon carbide crystalline material. The silicon carbide crystalline material may have a 4H crystal structure, 6H crystal structure, or other crystal structure. The semiconductor workpiece can be an on-axis workpiece (e.g., end face parallel to the (0001) plane) or an off-axis workpiece (e.g., end face non-parallel to the (0001) plane).

Aspects of the present disclosure may make reference to a surface of the semiconductor workpiece. In some examples, the surface of the workpiece may be, for instance, a silicon face of the workpiece. In some examples, the surface of the workpiece may be, for instance, a carbon face of the workpiece.

In some examples, a semiconductor wafer may be a solid semiconductor workpiece upon which semiconductor device fabrication may be implemented. A semiconductor wafer may be a homogenous material, such as silicon carbide, and may provide mechanical support for the formation and/or carrying of additional semiconductor layers (e.g., epitaxial layers), metallization layers, and other layers to form one or more semiconductor devices. In some examples, a semiconductor wafer may have a thickness in a range of about 0.5 microns to about 1000 microns or greater, such as in a range of about 150 microns to about 400 microns, such as in a range of about 250 microns to about 350 microns. In some examples, the semiconductor wafer may include a thin semiconductor layer (e.g., about 0.5 micron or less, such as 0.1 microns to about 0.5 microns) on a carrier substrate.

Grinding is a material removal process that is used to remove material from the semiconductor wafer. Grinding may be used to reduce a thickness of a semiconductor wafer. Grinding typically involves exposing the semiconductor wafer to an abrasive containing surface, such as grind teeth on a grind wheel. Grinding may remove material of the semiconductor wafer through engagement with the abrasive surface.

Lapping is a precision finishing process that uses a loose abrasive in slurry form. The slurry typically includes coarser particles (e.g., largest dimension of the particles being greater than about 100 microns) to remove material from the semiconductor wafer. Lapping typically does not include engaging the semiconductor wafer with an abrasive-containing surface on the lapping tool (e.g., a wheel or disc having an abrasive-containing surface). Instead, the semiconductor wafer typically comes into contact with a lapping plate or a tile usually made of metal. Lapping typically provides better planarization of the semiconductor wafer relative to grinding.

Polishing is a process to remove imperfections and create a very smooth surface with a low surface roughness. Polishing may be performed using a slurry and a polishing pad. The slurry typically includes finer particles relative to lapping, but coarser particles relative to chemical mechanical planarization (CMP). Polishing typically provides better planarization of the semiconductor wafer relative to grinding.

CMP is a type of fine or ultrafine polishing, typically used to produce a smoother surface ready, for instance, for epitaxial growth of layers on the semiconductor wafer. CMP may be performed chemically and/or mechanically to remove imperfections and to create a very smooth and flat surface with low surface roughness. CMP typically involves changing the material of the semiconductor through a chemical process (e.g., oxidation) and removing the new material from the semiconductor wafer through abrasive contact with a slurry and/or other abrasive surface or polishing pad (e.g., oxide removal). In CMP, the abrasive elements in the slurry typically remove the product of the chemical process and do not remove the bulk material of the semiconductor wafer, often leaving very low subsurface damage.

Polishing tools (e.g., such as chemical mechanical polishing (CMP) tools) may be used after grinding operations to polish and/or smooth a semiconductor wafer surface. Polishing tools, such as CMP tools, may use a combination of chemical and mechanical forces to remove excess materials from a wafer surface, ensuring desired flatness and smoothness. Polishing tools, such as CMP tools, may include a rotating platen, polishing pad, and a slurry containing abrasive particles and chemical agents. As the wafer is pressed against the polishing pad and rotated, the slurry chemically reacts with and/or mechanically removes material, resulting in a highly planar and smooth surface.

Electrochemical Mechanical Polishing (ECMP) is a specialized process used in semiconductor manufacturing for polishing and planarizing surfaces with high precision. ECMP combines the principles of electrochemical and mechanical actions to achieve highly uniform material removal rates across the surface of a semiconductor wafer. For example, a silicon carbide semiconductor wafer may be mounted or provided on a workpiece carrier, which brings the wafer into contact with a polishing pad. A slurry (including an electrolyte solution) may be applied between the semiconductor wafer and the polishing pad to facilitate the electrochemical reactions, carry away removed material, and provide lubrication for the mechanical polishing action. A bias (e.g., bias voltage and/or bias current) may be applied between the semiconductor wafer and the electrolyte solution of the slurry to drive electrochemical reactions to occur at the surface of the semiconductor wafer, leading to material dissolution. The electrochemical reactions may vary depending on the specific materials involved, but they often involve oxidation or reduction processes.

For ECMP, while the electrochemical reactions are occurring, mechanical forces may be applied to the wafer through the polishing pad. These mechanical forces help to enhance material removal and ensure a uniform polishing action across the substrate surface. As the ECMP process continues, material is gradually removed from the surface of the workpiece, resulting in planarization and smoothing of the surface. The combination of electrochemical and mechanical actions allows for precise control over material removal rates and surface finish (e.g., through control of bias (e.g., bias voltage, bias current) applied to the semiconductor wafer).

To enhance the effectiveness of the ECMP process, the slurry can contain both an electrolyte to facilitate the electrochemical redox reaction and abrasive particles to effectively remove the electrochemical reaction products (e.g., oxides) after anodic oxidation, or in order to increase removal rates. The abrasive particles can be in particle or colloidal form. As used herein, an abrasive particle will refer to both particulate and colloidal forms of abrasive components.

For the abrasive components to be stable in the slurry (i.e., for them not to coagulate, sediment, or precipitate), typically a surfactant is used, or the pH is tightly controlled. However, the ionic compounds used to optimize the electrolytic and electrochemical properties of the slurry can destabilize the abrasive particles. Due to the trade-off between electrolytic effectiveness and abrasive particle stability, present ECMP slurries exhibit insufficient stabilization of abrasive particles, omit the use of abrasive particles, use less effective abrasive particles, or compromise on the electrolytic or electrochemical properties of the slurry by low volume fractions or less effective components. Some slurries depend on using strong oxidizers, such as KMnO₄ or HF, which are of environmental and safety concern.

Accordingly, example aspects of the present disclosure are directed to enhancing abrasive particle stabilization, electrolytic conduction, and electrochemical activity by ionic compound design. The use of tailored ionic components may allow for stabilization of the particles within the slurry. Tailoring the ionic components may be achieved by selecting cations and anions for their respective tasks for stabilizing the abrasive particle and creating an efficient electrochemical reaction. One ionic species (e.g., the cation) can bond to the abrasive particle via a direct or induced electrostatic or covalent attraction, while the anion can be tailored for highest effectivity regarding ionic conductivity and kinetics at the workpiece surface. As such, the slurry is tuned for effective polishing/grinding processes and, advantageously, does not create the environmental and safety concerns of strong oxidizers.

As used herein, “bond,” “bonding,” or “bonded” may refer to any suitable link between species, including strong bonds such as covalent and ionic bonds as well as weaker bonds, such as hydrogen bonds, Van der Waals interactions, hydrophobic bonds, electrostatic attractions, ion-dipole interactions, dipole-dipole interactions, and the like.

As will be described in further detail below, one proposed design for an organic cation that can stabilize an abrasive particle within the slurry and provide the desired electrochemical properties uses a well-established chemical pathway for forming solution stable electron deficient organic species (i.e., cations). This synthetic approach uses the ability of neutral electron rich atoms, such as nitrogen, oxygen, sulfur, and phosphorous, to form sigma bonds to carbon to produce a solution stable organic cation. A neutral aromatic nitrogen, for example, can produce a stable single bond to carbon where the electron is shared between the two atoms and a net positive charge resides on the nitrogen. Such organic cations are utilized in the field of organic electrochemistry for their charged ground state and reversible redox states. The cations are paired with a carefully chosen anion to tune chemical properties like solubility and aggregation. In the solid state, they can reside as stable ionic solids, analogous to inorganic salts. These electron deficient species are tunable through molecular design to achieve the desired electrochemical properties. The positive charge functions as the primary stabilizer for abrasive slurry particles in the slurry. To this core molecular design for the cation, carefully chosen constituents may be appended which serve to link the molecule to the abrasive particle, tune polarity, and optimize steric effects.

In some example embodiments, a small anion is paired with the cation to allow for effective oxidation of partially oxidized or rough surfaces of the semiconductor workpiece. The oxidized layer (e.g., of SiO₂ or other oxides including mixed oxides such as SiC: SiO₂) formed electrochemically on the semiconductor workpiece then needs to be removed chemically and/or mechanically to avoid passivation and to expose the fresh wafer surface for continuous electrochemical oxidation. In this regard, the abrasives in the slurry may interact with the oxidized layers via adsorption (chemisorption, physisorption, magnetic attraction, and others) and, along with the pad action, help to mechanically break down the oxidized layer to aid material removal. Some abrasive types, such as ceria, can even chemically bind to SiO₂ and facilitate material removal.

In some embodiments, some or all of the abrasive particles in the slurry can be provided to the slurry from the polishing pad or a grind disc material. For example, they may be released from the pad during a conditioning process and will be affected by the choice of anionic/cationic compounds in the slurry.

In some embodiments, the cations/anions can exhibit stabilization and attachment functions that include steric, ionic, oleophilic, or hydrophilic properties. For example, the cations or anions may function as surfactants, which are capable of sterically or electrostatically stabilizing the abrasive particles in the slurry. Surfactants may also be added to the slurry as an additional component. Depending on the pH and the isoelectric points of the workpiece (e.g., SiC wafer) and the abrasive, either cationic or anionic surfactants can be used to stabilize negatively or positively charged abrasive particles, respectively. Zwitterionic surfactants, containing both cationic and anionic activity, can also be used for the same purpose, and the cationic or anionic nature of such zwitterionic surfactants can be controlled by the slurry pH. Moreover, surfactants may be water soluble, allowing the slurry to be an aqueous medium, providing the polar protic chemical environment ideal for an ECMP slurry, while offering the advantage of steric hindrance to stabilize abrasives.

In some embodiments, ionic compounds like NaCl, NaNO₃, KCl, NaNO₃, or NH₄F can be added as electrolyte components in which Na+, K+, or NH₄+ form cations and Cl—, NO3-, or F-form anions to increase the ionic strength of the slurry. The strong ionic nature of such an ECMP slurry may have added benefits to further enhance the chemical dissolution of the oxidized layer formed during ECMP. For example, when the oxidized layer contains SiO₂, the anions may act as strong nucleophiles or electron rich species to chemically attack the electron deficient Si atom of SiO₂ to promote bond breaking and hydrolysis, leading to the formation of soluble silica species such as silicic acid. Protonation and deprotonation of these soluble silica species may further enhance the ionic and nucleophilic activity of the ECMP slurry.

In some example embodiments, a polishing system is disclosed, which may include an ECMP tool including a platen with a polishing pad for polishing a semiconductor workpiece such as a silicon carbide semiconductor wafer. The polishing system may include a workpiece carrier to bring a surface of a silicon carbide semiconductor wafer against the polishing pad on the platen. The platen with the polishing pad may be operable to rotate about an axis. To help facilitate the electrochemical reactions of ECMP, the polishing pad may be operable to provide an electrically conductive path for charge carriers through the polishing pad to a bias source (e.g., voltage source and/or current source). As used herein, charge carriers may be, for instance, ions, electrons, protons, or other particles carrying a charge.

The polishing system may include a delivery system that may deposit the slurry onto the polishing pad. For example, the polishing system may include a slurry delivery system that deposits the slurry onto the polishing pad.

The polishing system may include a workpiece electrode and a bias source (e.g., voltage source and/or current source) to initiate electrochemical reactions at the surface of the silicon carbide semiconductor wafer. The bias source may be configured to provide a bias voltage and/or a bias current between the silicon carbide semiconductor wafer and, for instance, the electrolyte solution of the slurry. The polishing pad may provide an electrically conductive path for one or more charge carriers from the electrolyte solution (e.g., as part of the slurry) through the polishing pad to the bias source. This can cause electrical contact between the surface of the semiconductor wafer and the electrolyte solution through the surface of the polishing pad for ECMP.

The temperature, heating or cooling, of the platen, workpiece carrier, and/or slurry delivery system can be controlled. For example, temperature can be used to control reactivity and stability of components in the electrochemical mechanical polishing process.

Advantages provided by the ionic slurry described herein include the ability to facilitate an ECMP process using a slurry which has an effective amount of stabilized abrasive particles while also having good electrolytic properties. Additionally, the slurry does not rely on strong oxidizers having environmental and safety concerns to achieve this. Further, due to the stability of the slurry, and suspension in particular, it may be re-circulated within the system, thus further improving the material consumption and environmental impact.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure may refer to a “pad.” In some cases, a pad with increased stiffness, thickness, or other attributes may be commonly referred to as a “disc.” However, in the present disclosure, the terms “pad” and “disc” may be used interchangeably without altering the scope of the present disclosure.

In the drawings and specification, there have been disclosed typical embodiments and, although specific terms are employed, they are used in a generic and descriptive sense only and not for purposes of limitation of the scope set forth in the following claims.

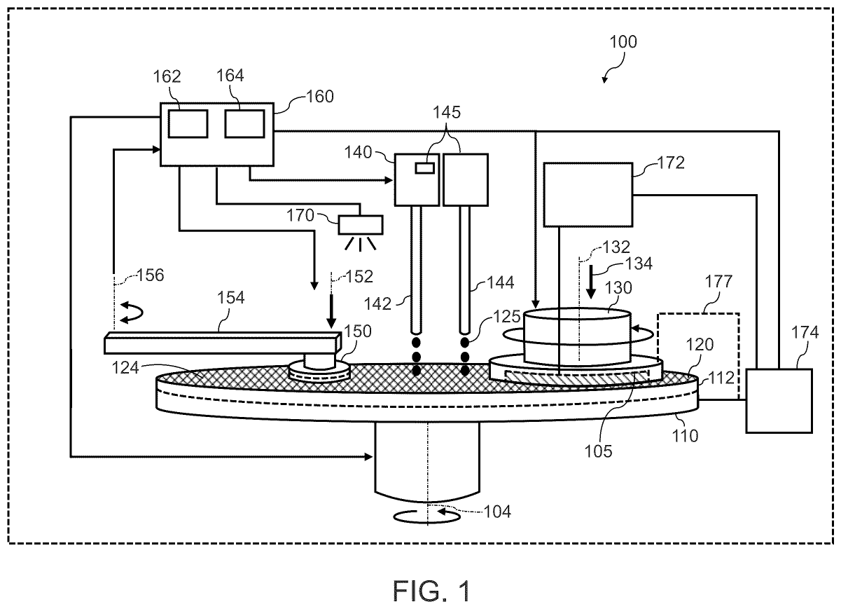

FIG. 1 depicts an example polishing system 100 for a semiconductor workpiece 105 according to example embodiments of the present disclosure. The polishing system 100 is an ECMP system operable to perform one or more polishing operations for the semiconductor workpiece 105. The semiconductor workpiece 105 may be a silicon carbide semiconductor workpiece such as, for example, a silicon carbide wafer. The silicon carbide wafer may include 4H silicon carbide, 6H silicon carbide or other crystal structure. The semiconductor workpiece 105 may be doped or undoped. In some examples, the polishing system 100 includes a platen 110 with a polishing pad 120, a workpiece carrier 130, a delivery system 140, a conditioning head 150, and a controller 160.

More specifically, the polishing system 100 includes the platen 110. The platen 110 may be operable to rotate about an axis 104. The platen 110 may be operable to rotate about the axis 104 in either a clockwise or counterclockwise direction. In some examples, the platen 110 may rotate, for instance, at a rotational speed in a range of about 15 rpm to about 10000 rpm, such as about 15 rpm to about 7500 rpm, such as about 15 rpm to about 2000 rpm, such as about 15 rpm to about 1000 rpm, such as about 15 rpm to about 500 rpm, such as about 15 rpm to about 120 rpm.

The polishing system 100 includes a polishing pad 120 on the platen 110. For instance, the platen 110 may include a receptacle 112. The receptacle 112 may be configured to hold a polishing pad 120 for an ECMP process. The receptacle 112 may be a surface configured to support or receive the polishing pad 120. In some examples, the receptacle 112 may be a planar surface that supports the polishing pad 120.

The polishing pad 120 may provide a surface for polishing the semiconductor workpiece 105. The polishing pad 120 may include durable and chemically resistant materials such as polyurethane and/or polyether ether ketone (PEEK) material. The polishing pad 120 may have a surface with a specified roughness and porosity to facilitate polishing a semiconductor workpiece 105 (e.g., a silicon carbide semiconductor wafer). The polishing pad 120 may have one or more wear-resistant layers (e.g., diamond layers, diamond-like carbon layers, ceramic layers, etc.). The polishing pad 120 may include grooves or dimples to increase slurry distribution and reduce edge effects during the ECMP process. As further described herein, the polishing pad 120 includes a particular structure to help provide an electrically conductive path for charge carriers for instance, through electrical conduction or by providing structures (e.g., voids) to accommodate an electrolyte solution.

The polishing pad 120 may include a cushioning layer (e.g., foam or rubber), in some examples, to facilitate adaptation of the polishing pad 120 to the topography of the semiconductor workpiece 105, providing improved planarity of the semiconductor workpiece 105.

The polishing pad 120 may have a diameter. The diameter may be greater than a size of the semiconductor workpiece 105. The polishing pad 120 may have a diameter in a range of, for instance, about 150 mm to about 820 mm, such as in a range of about 150 mm to about 400 mm, such as in a range of about 150 mm to about 300 mm. In some examples, the diameter of the polishing pad 120 may be smaller or nearly the same size as the diameter of the platen 110 (FIG. 1). In some examples, the diameter of the polishing pad 120 may be smaller than the diameter of the platen 110 and/or a support layer to allow for top contact of the bias source to the platen 110 and/or the support layer. However, the diameter of the polishing pad 120 may be larger than the diameter of the platen 110 without deviating from the scope of the present disclosure. In some examples, the polishing pad 120 may have a thickness in a range of about 1 millimeter to about 40 millimeters, such as in a range of about 1 millimeter to about 20 millimeters, such as in a range of about 1 millimeter to about 7 millimeters.

In some examples, the polishing pad 120 may include an abrasive containing surface. The abrasive surface may include an abrasive containing material. The abrasive containing material may be suitable for polishing or surface processing of silicon carbide. The abrasive containing material may include a plurality of abrasive elements (e.g., abrasive particles) in a host material or matrix. In some examples, the host material may include one or more vitreous material, metal, resin, and/or other sintered material and/or organic material. In some examples, the abrasive elements may be diamond or a diamond coated material. In some examples, the abrasive elements may include a ceramic material. Example ceramic materials may include, for instance, boron carbide (B+C) and cubic boron nitride (BN). In some examples, the abrasive elements may include one or more metal oxides (sintered and/or unsintered). In some embodiments, the abrasive elements may include silica, ceria, zirconia, alumina, silicon carbide, nitrates, and/or other carbides and in general one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

In some examples, the polishing pad 120 has an abrasive storing material. The abrasive storing material may hold abrasive particles or elements (e.g., from a slurry used in an ECMP operation). The abrasive particles or elements held by the polishing pad 120 may provide an abrasive surface for performing an ECMP operation. In some examples, the polishing pad 120 does not include a surface with abrasive elements.

In some examples, the polishing pad 120 may provide an electrically conductive path for one or more charge carriers through the polishing pad 120 to a bias source 174, allowing for charge carriers to move from the surface, side, or backside of the polishing pad 120 to the surface of a workpiece. Methods of conduction of charge carriers can be by electronic transport of electrons or holes, ionic conduction of protons or other ions, fluid transport of any particles carrying a charge. Charge transport may be a general property, independent of the driving forces such as electrical potential, diffusion, or thermal-, pressure-, and other gradients.

In some examples, the resistivity of the electrically conductive path through a thickness of the polishing pad 120 may be in a range of about 1 microOhm/cm² to about 500 Ohm/cm². The resistivity through the thickness of the polishing pad 120 may be different for different types of charge carriers. In some examples, the resistivity of the electrically conductive path through a thickness of the polishing pad 120 may be in a range from about 1 microOhm/cm² to about 0.1 Ohm/cm². In some examples, the resistivity of the electrically conductive path through a thickness of the polishing pad 120 may be in a range from about 0.1 Ohm/cm² to about 200 Ohm/cm², such as about 1 Ohm/cm² to about 100 Ohm/cm², such as about 2 Ohm/cm² to about 50 Ohm/cm². In some examples, the resistivity of the electrically conductive path through a thickness of the polishing pad 120 may be in a range from about 0.1 Ohm/cm² to about 500 Ohm/cm², such as about 2 Ohm/cm² to about 200 Ohm/cm², such as about 4 Ohm/cm² to about 100 Ohm/cm².

In some examples the polishing pad 120 may have a sheet resistance in a radial direction of the polishing pad in a range of about 6 microOhm·m/m to about 200 Ohm·m/m. The sheet resistance in the radial direction of the polishing pad 120 may be different for different types of charge carriers. In some examples, the polishing pad 120 may have a sheet resistance in a range of about 6 microOhm·m/m to about 250 milliOhm·m/m. In some examples, the polishing pad 120 may have a sheet resistance in a range of about 0.25 Ohm·m/m to about 2.0 Ohm·m/m, such as about 0.5 Ohm·m/m to about 1 Ohm·m/m, such as about 0.5 Ohm·m/m to about 0.75 Ohm·m/m in a radial direction of the polishing pad 120. In some examples, the polishing pad 120 may have a sheet resistance in a range of about 0.25 Ohm·m/m to about 200 Ohm·m/m, such as about 0.5 Ohm·m/m to about 100 Ohm·m/m, such as about 0.5 Ohm·m/m to about 75 Ohm·m/m in a radial direction of the polishing pad 120. The electrically conductive path provided by the polishing pad 120 in these ranges may provide for greater uniformity in the electrochemical reactions occurring at the workpiece 105.

In some examples, the material of the polishing pad 120 may include metal or metallic elements, a matrix, or metal bonds. The metal materials can contain catalysts that may be used to activate chemistry that contributes to the oxidation of the workpiece 105. Those metals may include, for instance, noble metals, such as platinum, gold, silver, palladium, or other metals and their oxides, such as ruthenium, iridium, iron, nickel, copper, or aluminum. In these cases, the electrical resistivity through a thickness of the polishing pad 120 can be in the range of 1 micro-Ohm/cm² to 100 milli-Ohm/cm² or higher, and the sheet resistance in a radial direction can be in a range of 6 microOhm m/m to about 250 milliOhm m/m or higher.

In some examples, a surface polishing pad with a large resistance may be compensated with the increased flow of electrolyte (e.g., electrolyte slurry). This may allow the electrolyte fluid to move through voids (e.g., open pore system, channels, apertures, holes, etc.) in the polishing pad 120, contributing to conductive paths in the polishing pad 120.

The delivery system 140 may be used to deliver the slurry to the polishing pad 120 held on the platen 110 during an ECMP process. The slurry may be delivered, for instance, from a slurry delivery outlet 142. As described in further detail below, the slurry includes abrasive particles that allow a polishing pad to physically remove material from the surface, aiding in material removal and achieving the desired surface finish. These abrasive particles may include fine-grained materials such as silicon dioxide (SiO₂), alumina (Al₂O₃), ceria (CeO₂), and other suitable nanoparticles or microparticles.

The slurry generally includes electrolyte solution and abrasive particles. More specifically, the slurry includes a solvent, an abrasive particle, and an ionic compound comprising a cation and an anion. The electrolyte solution includes the solvent and the ions (i.e., electrolytes), which serve as charge carriers for the ECMP process. For example, the electrolytes aid in the polishing process by aiding in material removal and controlling surface finish and can be used to facilitate an electrically conductive path through the polishing pad. It should be understood that the slurry may comprise a solution, colloid, or suspension. For example, in some embodiments, the slurry may be delivered as a solution of the electrolyte in the solvent and the abrasive particle may be transferred to the slurry from the polishing pad. In other embodiments, the slurry may contain the abrasive particles as a suspension or colloid. The slurry is described in greater detail below.

The delivery system 140 may further include one or more fluid delivery outlets 144. The fluid delivery outlets 144 may be configured to provide one or more fluids (e.g., coolant, additive, lubricant, etc.) to the polishing pad 120 during a polishing process.

In some examples, the delivery system 140 may include an additive delivery system 145 configured to deliver one or more additives either with the slurry through the slurry delivery outlet 142 or separate from the slurry through the fluid delivery outlet 144. In some examples, the additive may be, for instance, one or more of, an etchant, an abrasive containing additive, an actuatable additive, a surfactant, or a lubricant.

Those of ordinary skill in the art, using the disclosures provided herein, will understand that the delivery system 140 may deliver materials (e.g., slurry) to the polishing pad 120 in various ways without deviating from the scope of the present disclosure, such as from a plurality of fluid delivery outlets, from apertures in the platen and/or the polishing pad, or from other fluid delivery techniques.

The polishing system 100 includes a workpiece carrier 130. The workpiece carrier 130 is operable to bring one or more semiconductor workpieces 105 into contact with the polishing pad 120 to implement a polishing process. In some examples, the workpiece carrier 130 may be operable to hold a semiconductor workpiece 105 for single wafer processing. In some examples, the workpiece carrier 130 may be operable to hold a plurality of semiconductor workpieces 105 for batch processing.

The workpiece carrier 130 may be operable to rotate the semiconductor workpiece 105 about an axis 132. The axis 132 is not aligned with the axis 104 associated with the platen 110. The workpiece carrier 130 may be operable to rotate the semiconductor workpiece 105 about the axis 132 in either a clockwise or counterclockwise direction. In some examples, the workpiece carrier 130 may rotate, for instance, at a rotational speed in range of about 15 rpm to about 10000 rpm, such as about 15 rpm to about 7500 rpm, such as about 15 rpm to about 2000 rpm, such as about 15 rpm to about 1000 rpm, such as about 15 rpm to about 500 rpm, such as about 15 rpm to about 120 rpm. The workpiece carrier 130 may rotate in the same direction as the platen 110 or in a different direction relative to the platen 110.

The workpiece carrier 130 may be able to provide a downforce 134 of the semiconductor workpiece 105 against the polishing pad 120. The downforce 134 of the workpiece carrier 130 may be controlled to adjust the polishing rate of the polishing process of the semiconductor workpiece 105.

The workpiece carrier 130 may also oscillate in a lateral direction along the surface of the polishing pad 120. This will allow exposure of the semiconductor workpiece 105 to different portions of the polishing pad 120 (e.g., at different radii of the polishing pad 120) during a polishing operation.

In some examples, the workpiece carrier 130 may include an electrically conductive head that may be used to provide a bias from a bias source (e.g., bias source 174) to the semiconductor workpiece 105. Other suitable mechanisms for providing a bias to the workpiece 105 may be implemented without deviating from the scope of the present disclosure.

The polishing system 100 may include a conditioning head 150. The conditioning head 150 may rotate about an axis 152, such that the conditioning head 150 rotates along the surface of the polishing pad 120 (e.g., in either a clockwise or counterclockwise direction). In some examples, the conditioning head 150 may be on a swing arm 154 that may swing about an axis 156 to move the conditioning head 150 to different locations on the polishing pad 120. The conditioning head 1500 may include an abrasive-containing material that is used to condition or dress the polishing pad 120 as the polishing pad 120 is subject to glazing during a polishing process.

The polishing system 100 includes one or more control devices, such as a controller 160. The controller 160 may include one or more processors 162 and one or more memory devices 164. The one or more memory devices 164 may store computer-readable instructions that when executed by the one or more processors 162 cause the one or more processors 162 to perform one or more control functions, such as any of the functions described herein. The controller 160 may be in communication with various other aspects of the polishing system 100 through one or more wired and/or wireless control links. For instance, the controller 160 may control the platen 110, the workpiece carrier 130, the delivery system 140, the conditioning head 150, and/or the bias source 174 to implement polishing processes according to examples of the present disclosure. For example, the controller 160 may control the temperature, heating or cooling, of the platen 110, workpiece carrier 130, and/or delivery system 140 to influence reactivity and stability of components in the electrochemical mechanical polishing process.

For instance, in some examples, the controller 160 may control the delivery system 140 to deliver a material to the polishing pad 120. For instance, the controller 160 may control the delivery system 140 to provide the slurry to the polishing pad 120 (e.g., through one or more of slurry delivery outlet 142 and/or fluid delivery outlet 144).

To facilitate ECMP, the polishing system 100 may include a workpiece electrode 172 and a bias source 174. The workpiece electrode 172 may include an electrical conductor that provides an electrical contact to, for example, the semiconductor workpiece 105. The workpiece electrode 172 is illustrated as being separate from the workpiece carrier 130 for purposes of illustration and discussion. Those of ordinary skill in the art will understand that the workpiece electrode 172 may be a part of the workpiece carrier 130 (e.g., a metal or electrically conductive path in the workpiece carrier 130 in electrical contact with the semiconductor workpiece 105).

The bias source 174 includes a device or circuit that provides a bias voltage and/or bias current between the semiconductor workpiece 105 (e.g., via the workpiece electrode 172) and the electrolyte of the slurry (e.g., via the surface processing pad 120). For instance, the bias source 174 may be a voltage source configured to provide a controlled bias voltage between the semiconductor workpiece 105 and an electrolyte (e.g., within the slurry). The bias source 174 may be a current source configured to provide a controlled bias current to the semiconductor workpiece 105. In some examples, the bias voltage may be in a range of about 0.5 V to about 20 V, such as about 0.5 V to about 2 V, such as about 1V to about 10 V, such as about 8 V to about 20V. In some examples, the bias voltage and/or the bias current can be used to control selectivity of the removal process and/or to control other chemical processes in the electrolyte solution or at surfaces in contact with the electrolyte solution. In some examples, the workpiece electrode 172 may be placed in physical contact with the workpiece 105, while the bias source 174 may be coupled to an electrolyte solution (e.g., in the slurry) through the surface processing pad 120, the platen 110, or an intermediate layer therebetween. The bias source 174 may be coupled to the electrolyte solution in any suitable manner, such as through the bottom of the polishing pad assembly 124, a side of the polishing pad assembly 124 (e.g., polishing pad, adhesive layer, and/or support layer) and/or through a top of the polishing pad assembly. For instance, as indicated by dashed line 177, the bias source 174 may be coupled to the electrolyte solution through the workpiece carrier 130 (e.g., through a conductive path in a retaining ring of the workpiece carrier).

In some examples, an electrochemical reaction rate on the semiconductor workpiece 105 may be controlled by controlling the bias source 174. For instance, a bias current may be controlled to provide an increased reaction rate or a decreased reaction rate during a surface processing operation. For instance, a high bias current may lead to faster reaction rate and higher polishing rates. However, a lower bias current may lead to a slower reaction rate to allow time for mechanical removal (e.g., through abrasive elements in the slurry) of reactants on the workpiece 105 during the surface processing operation. Control of the bias current may allow for the bias voltage to fluctuate as needed to provide a constant bias current or regulated bias current to the semiconductor workpiece 105. The bias current and/or the bias voltage may be controlled or regulated to control and/or calculate or otherwise determine material removal rates from the workpiece 105.

As mentioned above, the slurry generally contains a solvent, an abrasive particle, and an ionic compound comprising a cation and an anion. In some example embodiments, the cation is bonded (e.g., via a first functional group) to the abrasive particle. In some embodiments, the cation may also contain a second functional group.

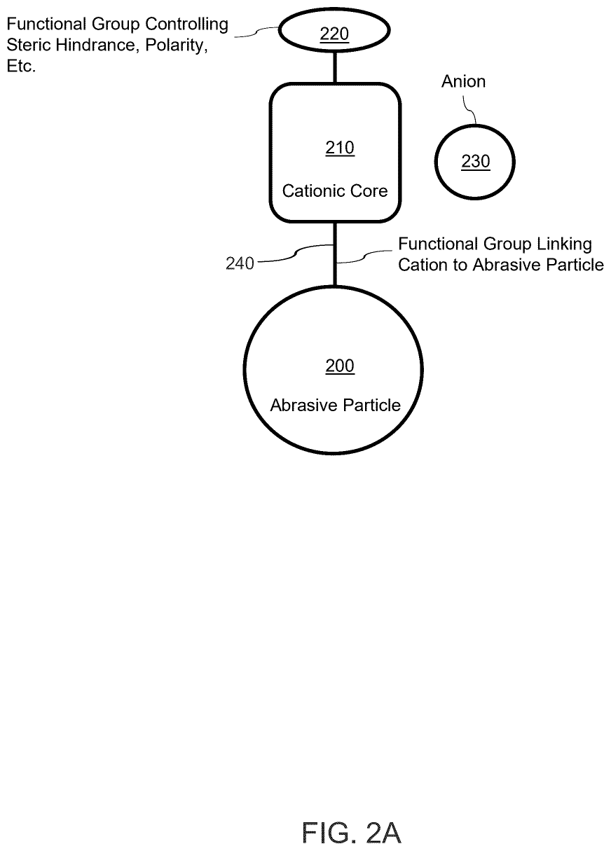

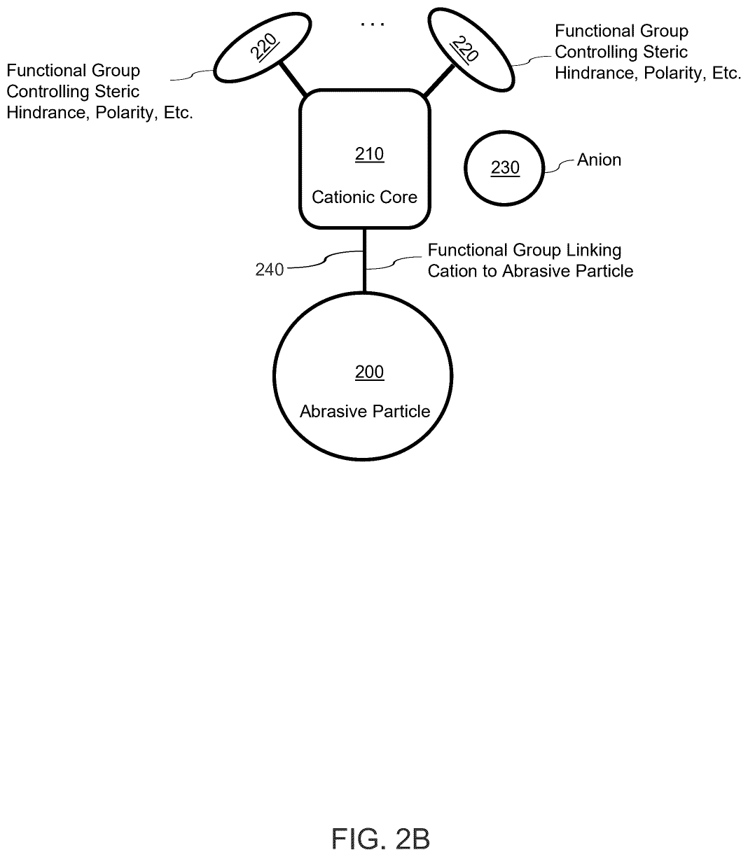

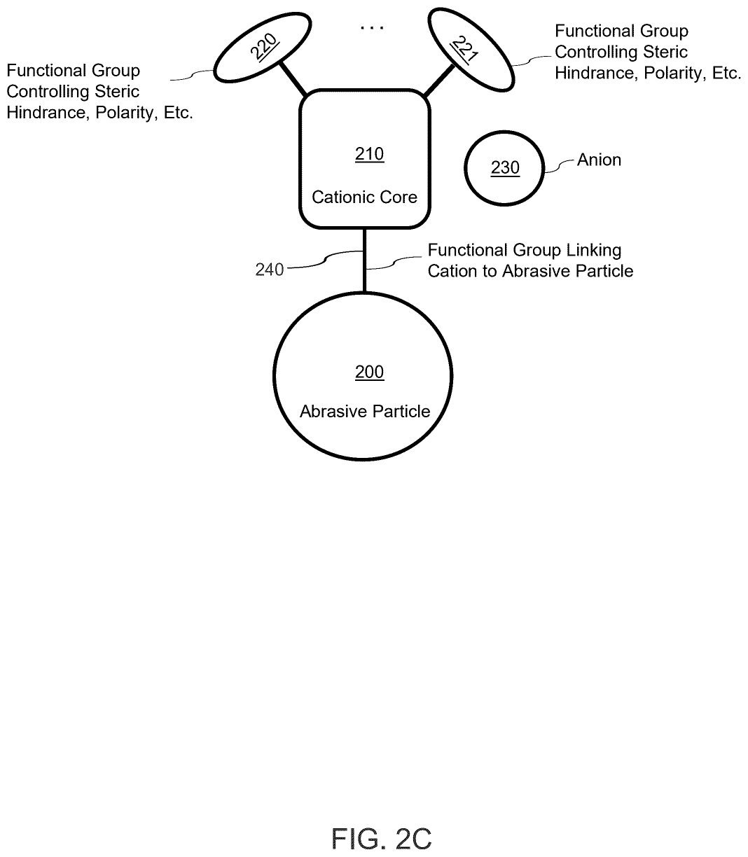

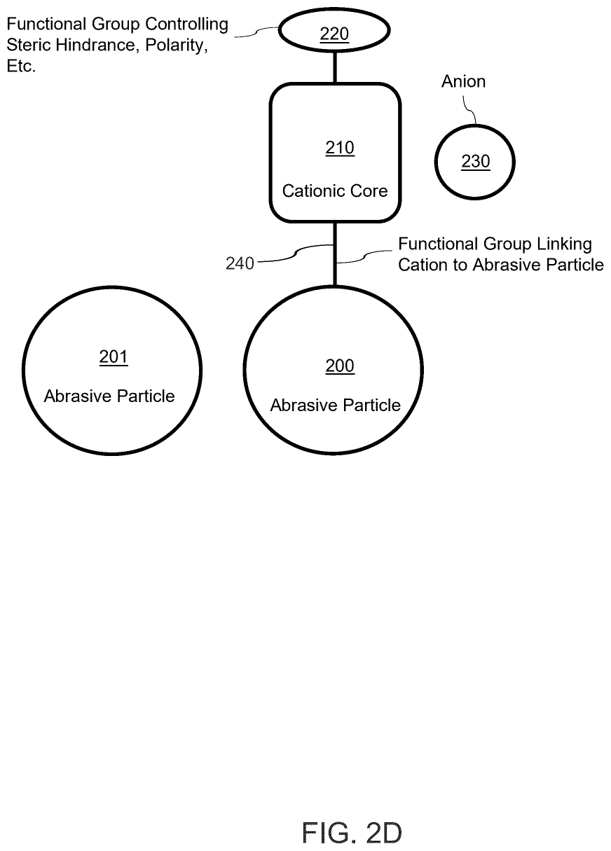

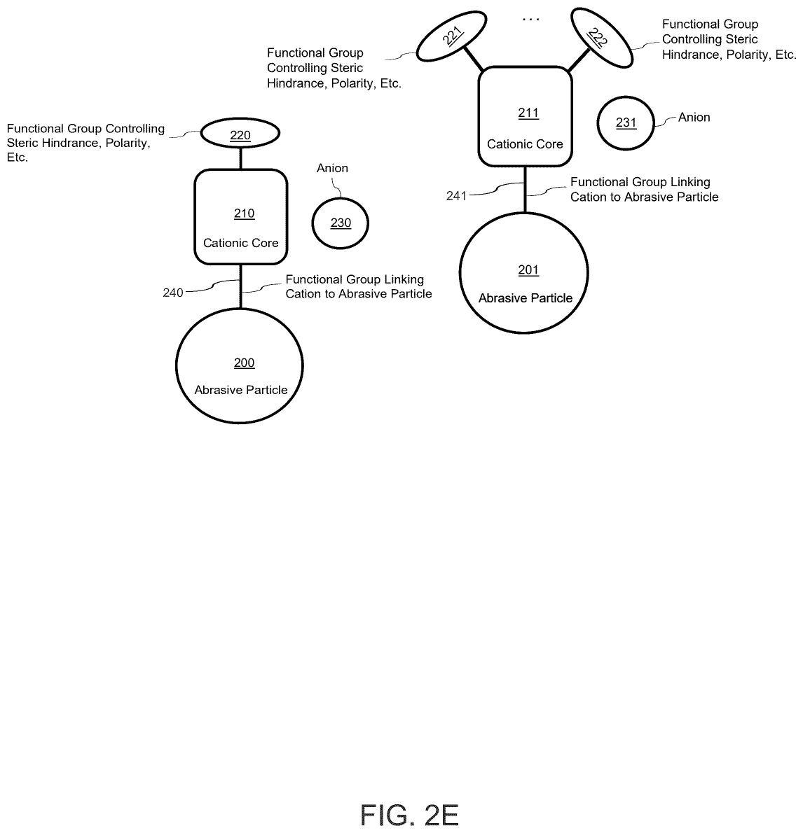

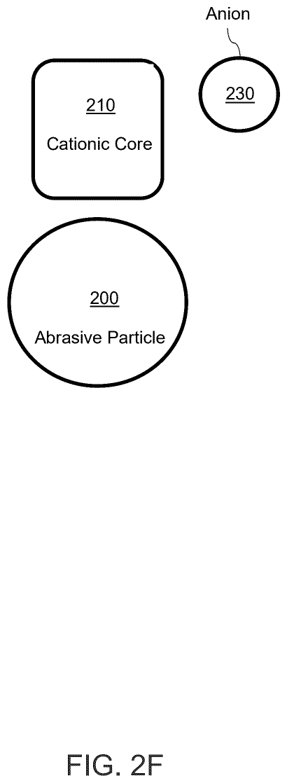

FIG. 2A shows a diagram of various components within the slurry according to one example embodiment. For example, it can be seen that a cationic core 210 is bonded to an abrasive particle 200 by a first functional group 240 attached to the cationic core 210. A second functional group 220 is also attached to the cationic core 210. The second functional group can be tailored for stability within the solvent. For example, the second functional group can be selected to enhance solubility, polarity, and/or provide optimal steric hindrance. The second functional group may also be selected for affinity to the semiconductor workpiece to promote interaction between the abrasive particle and the surface of the workpiece. An anion 230 is also shown. The anion 230 and cation (containing cationic core 210, first functional group 240 and second functional group 220) are free from each other within the solution. The anion may be selected for optimal electrolytic activity and penetration of the workpiece (e.g., silicon carbide wafer). The various components of the slurry are explained in further detail below.

In some embodiments, the solvent is a polar solvent. For example, in some embodiments, the solvent is water, such as deionized water. In other embodiments, the solvent is an organic solvent. For example, in some embodiments, the solvent is a polar aprotic organic solvent, such as N,N-dimethylformamide (DMF), acetonitrile (MeCN), tetrahydrofuran (THF), dimethylsulfoxide (DMSO), 1,2-Dimethoxyethane (DME), or dichloromethane (DCM). In other embodiments, the solvent is a polar protic solvent, for example, an alcohol, such as isopropanol or a glycol. In other embodiments, the solvent can be a nonpolar organic solvent, such as 1,4-difluorobenzene or dipropyl ether (DPE). In some embodiments, the solvent comprises mixtures of one or more of such solvents.

The abrasive particle may include silica, ceria, zirconia, alumina, silicon carbide, nitrates, and/or other carbides and in general one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide. The abrasive particle may also include an electrically charged particle, such as one of the previously listed materials having a surface that is stabilized by an anionic or cationic species bonded (e.g., by covalent, ionic, or hydrogen bonds; Van der Waals interactions; hydrophobic bonds; electrostatic attractions; ion-dipole interactions, dipole-dipole interactions; and the like) to the surface, or via a core-shell or coated particle having a polar surface that leads to ion adhesion or electrostatic stabilization. As used herein, the abrasive particle may refer to a plurality of abrasive particles of a single type or multiple different types of particles. For example, the abrasive particle can include a mixture of particles contained in the slurry as provided to the polishing pad (e.g., via slurry delivery outlet 142) and abrasive particles removed from the polishing pad. For example, as a polishing operation proceeds, abrasive particles contained within the polishing pad may be released into the slurry. In some embodiments, the abrasive particles in the slurry may all originate in the polishing pad. In such embodiments, the slurry can be delivered to the polishing pad as only the electrolyte solution (e.g., the ionic compound dissolved in the solvent). When the slurry delivered to the polishing pad contains abrasive particles and further abrasive particles are released from the polishing pad, the abrasive particles delivered in the slurry may be the same as or different from the abrasive particles released from the polishing pad.

The abrasive particles may have any suitable particle size. For example, in some embodiments, the abrasive particles may have a weight average particle size from about 1 nm or more, such as about 5 nm or more, such as about 10 nm or more, such as about 20 nm or more, such as about 30 nm or more, such as about 40 nm or more, such as about 50 nm or more, such as about 60 nm or more such as about 70 nm or more, such as about 80 nm or more, such as about 90 nm or more. The abrasive particles may have a weight average particle size of about 1000 nm or less, such as about 750 nm or less, such as about 500 nm or less, such as about 250 nm or less, such as about 150 nm or less, such as about 100 nm or less, such as about 90 nm or less, such as about 80 nm or less, such as about 70 nm or less, such as about 60 nm or less, such as about 50 nm or less, such as about 40 nm or less, such as about 30 nm or less, such as about 20 nm or less.

The abrasive particles may be contained in the slurry in an amount of about 0.01 wt. % or more, such as about 0.1 wt. % or more, such as about 0.5 wt. % or more, such as about 1 wt. % or more, such as about 3 wt. % or more, such as about 4 wt. % or more. The abrasive particles are typically contained in the slurry in an amount of about 5 wt. % or less, such as about 4 wt. % or less, such as about 3 wt. % or less, such as about 2 wt. % or less, such as about 1 wt. % or less, such as about 0.5 wt. % or less, such as about 0.4 wt. % or less, such as about 0.3 wt. % or less, such as about 0.2 wt. % or less, such as about 0.1 wt. % or less.

The ionic compound contains a cation and an anion. In some embodiments, the ionic compound is a solid at ambient conditions (e.g., about 20° C.). In some embodiments, the ionic compound is an ionic liquid. For example, the ionic compound may be a liquid at relatively low temperatures, such as about 100° C. or less, such as about 50° C. or less, such as at about 20° C. In some embodiments, when an ionic liquid is used, the solvent can be omitted, and the slurry may comprise the abrasive particles suspended within the ionic liquid. In other embodiments, an ionic liquid may be used in combination with a solvent. For example, the slurry may contain an ionic liquid dissolved in the solvent (e.g., water).

As mentioned above, the ionic compound may be optimized for the ECMP process. For example, in some embodiments, the ionic compound contains either a cation or an anion configured to stabilize the abrasive particles within the slurry. Whether the cation or the anion stabilizes the abrasive particles can depend on the pH of the slurry. In some embodiments, for example, the pH of the slurry is relatively high, such as from about 7 to about 10, and the cation is configured to stabilize the abrasive particles. In other embodiments, the anion is configured to stabilize the abrasive particle. In such embodiments, the pH may be relatively low, such as from about 2 to about 7. In some embodiments, for example, the abrasive particle exhibits a negative surface charge at the pH of the slurry and the cation is configured to stabilize the particle. In other embodiments, the abrasive particle exhibits a positive surface charge at the pH of the slurry and the anion is configured to stabilize the particle.

As shown in FIG. 2A, the first functional group 240 can be configured to bond to the abrasive particle 200. The second functional group 220 can be configured to control the stability of the cation within the solvent and/or affinity for the workpiece. As the cations within the slurry are dissolved in the solvent and linked to the abrasive particles, they stabilize the abrasive particles within the slurry (e.g., keep them suspended within the slurry).

The cation is not limited to having only two functional groups. For example, as shown in FIG. 2B, the cation may contain a first functional group 240 linking the cation to the abrasive particle 200 and multiple additional functional groups 220, which may each be selected to provide stability within the slurry. For example, the additional functional groups 220 may be selected to provide steric hindrance, solubility, hydrophilicity, oleophilicity, affinity for the workpiece, etc.

The additional functional groups may be the same or different from each other. For example, FIG. 2B shows an example embodiment in which the cation contains multiple functional groups 220 controlling steric hindrance, polarity, etc. that are the same as each other. FIG. 2C, on the other hand, shows an example embodiment in which the cation contains multiple functional groups 220 and 221 controlling steric hindrance, polarity, etc. that are different from each other. It should be understood that, as indicated by the ellipsis in FIGS. 2A and 2B, more than two functional groups in addition to the first functional group 240 may be attached to the cationic core. Any further functional groups may be the same as or different from functional groups 220 or 221.

Further, as shown in FIG. 2D, not all abrasive particles in the slurry are necessarily bonded to a cation. For example, in FIG. 2D, abrasive particle 200 is stabilized by a cation, while abrasive particle 201 is not stabilized by a cation. Abrasive particles 200 and 201 may be formed from the same or different materials.

Furthermore, as shown in FIG. 2E, multiple different types of cations may be included in the slurry. For example, FIG. 2E shows an example embodiment in which an abrasive particle 200 is stabilized by a cation containing a cationic core 210, a first functional group 240 linking the cationic core to the abrasive particle 200, and a second functional group 220. The slurry also contains an abrasive particle 201 stabilized by a cation containing a cationic core 211, a first functional group 241 linking the cationic core to the abrasive particle 201, and two additional functional groups 221 and 222. The slurry also contains anions 230 and 231. The abrasive particles 200 and 201 may be formed from the same or different materials, the cationic cores 210 and 211 may be the same as or different from each other, the first functional groups 240 and 241 may be the same as or different from each other, the additional functional groups 220, 221, and 222, may be the same as or different from each other, and the anions 230 and 231 may be the same as or different from each other.

In other embodiments, as shown in FIG. 2F, the cation may not contain a functional group bonding the cationic core 210 to the abrasive particle 200. In such embodiments, the cation may be bonded to the abrasive particle 200 through non-covalent means, such as electrostatic forces or ion-dipole interactions. In such embodiments, the abrasive particle may have a negative surface charge. For example, in some embodiments, the abrasive particle may have acidic groups (e.g., carboxyl groups) at its surface, which can be deprotonated in the slurry to provide the negatively charged surface. The cation, having a positive charge, may then be bonded to the abrasive particle by an electrostatic force. In other embodiments, the abrasive particle may have polar groups on its surface and the cation may be bonded to the particle by an ion-dipole interaction.

In some embodiments, as shown in FIG. 2F, the cation may not contain any functional groups attached to the ionic core to provide stability (e.g., 220, 221, 222 in FIGS. 2A-2E). In such embodiments, the particles may be stabilized through electrostatic repulsion forces (e.g., a sufficient zeta potential) between particles, preventing them from flocculating. For example, cations may surround the abrasive particles within the slurry effectively creating a positively charged surface layer containing the positively charged cations. The positively charged surface layers of the abrasive particles act to repel each other to maintain stability in the solution.

In some embodiments, as shown in FIG. 2F, the cation may not contain any functional groups attached to the cationic core. In other embodiments, the cation may contain a functional group configured to bond to the abrasive particle (e.g., 240 in FIGS. 2A-2E) but no other functional groups (e.g., 220, 221, 222 in FIGS. 2A-2E). In other embodiments, the cation may contain a functional group configured to provide stability within the solution (e.g., 220, 221, 222 in FIGS. 2A-2E) but no functional group configured to bond to the abrasive particle (e.g., 240 in FIGS. 2A-2E).

It should be understood that the terms “first functional group” and “second functional group” are used herein for descriptive purposes and the ionic compound may contain a “second functional group” without containing a “first functional group”.

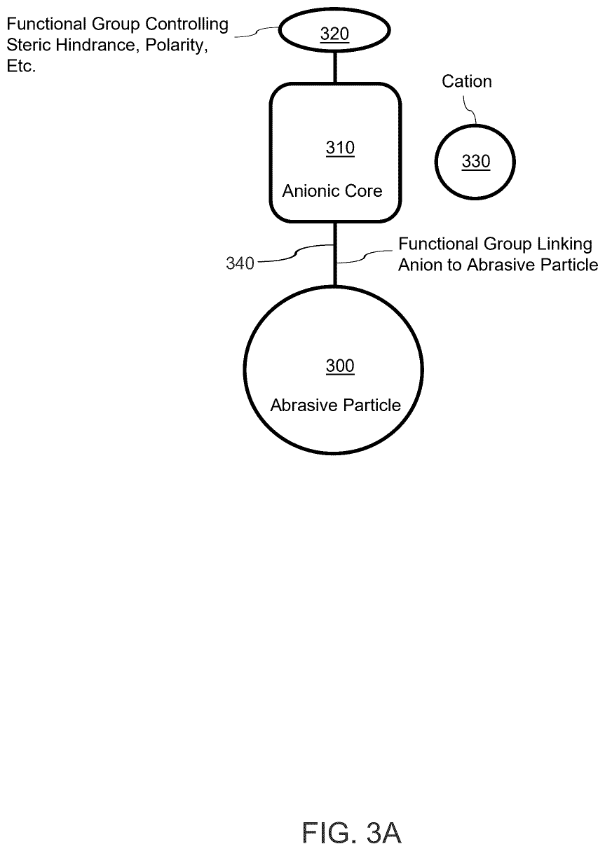

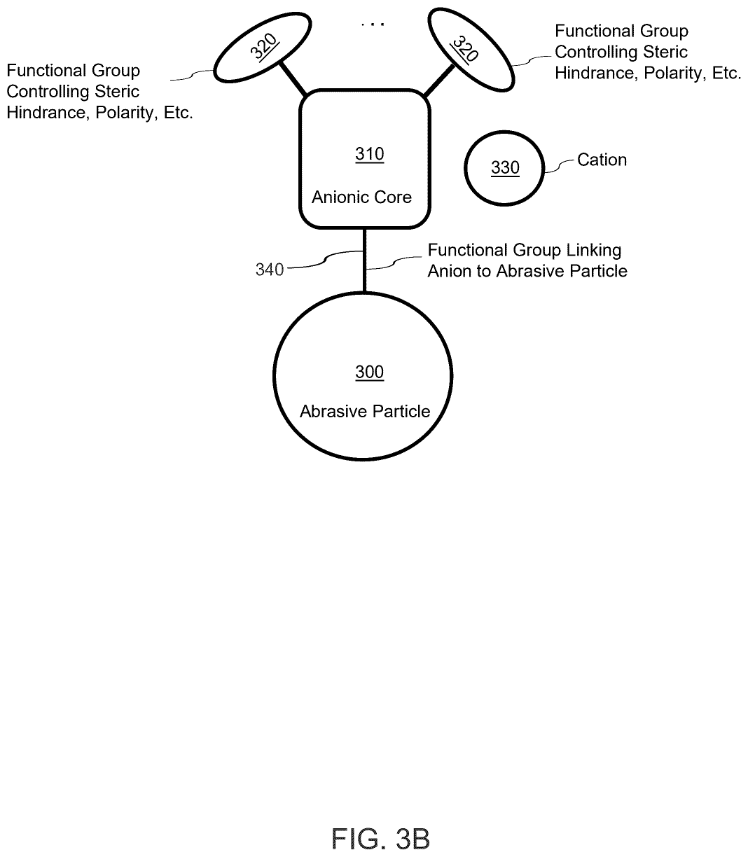

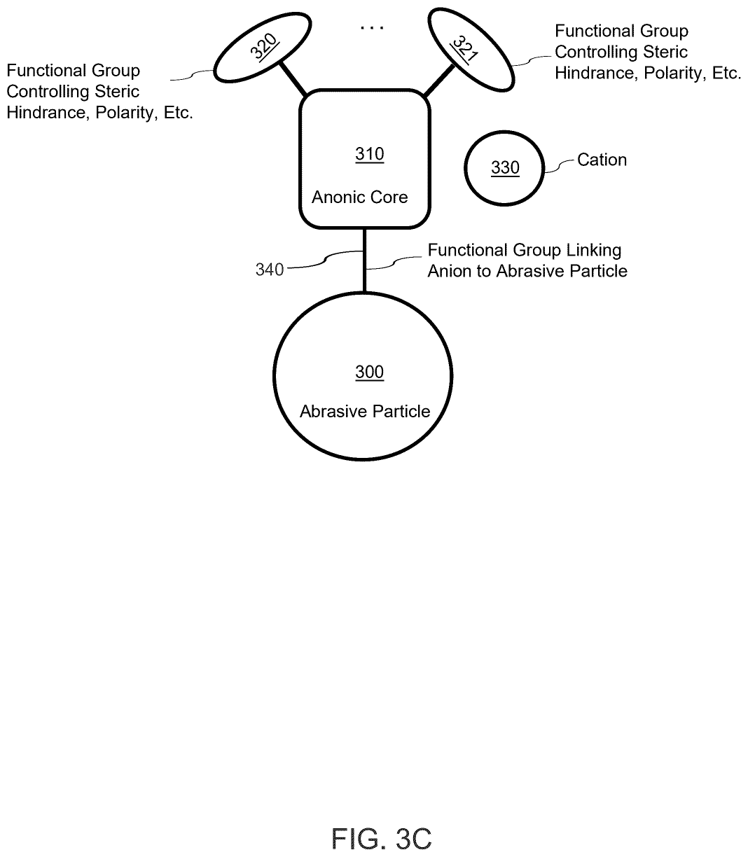

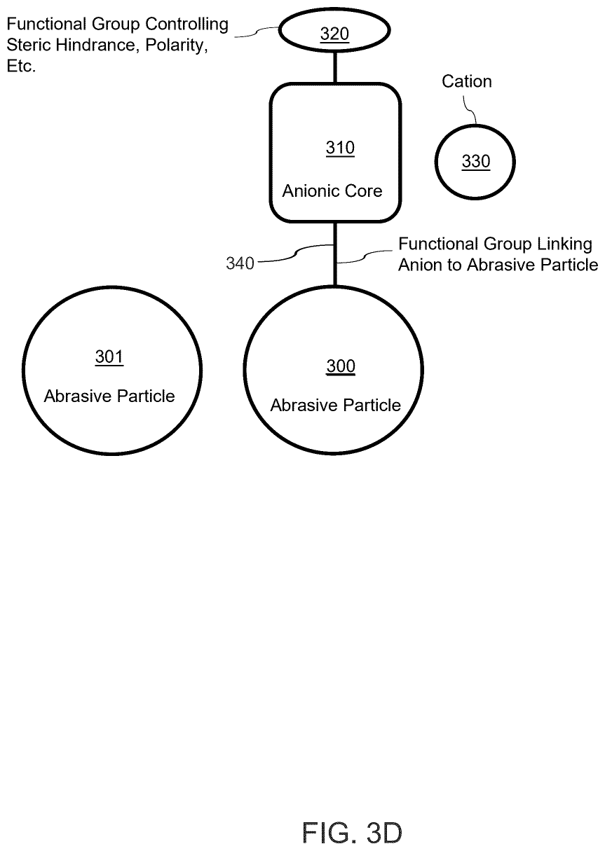

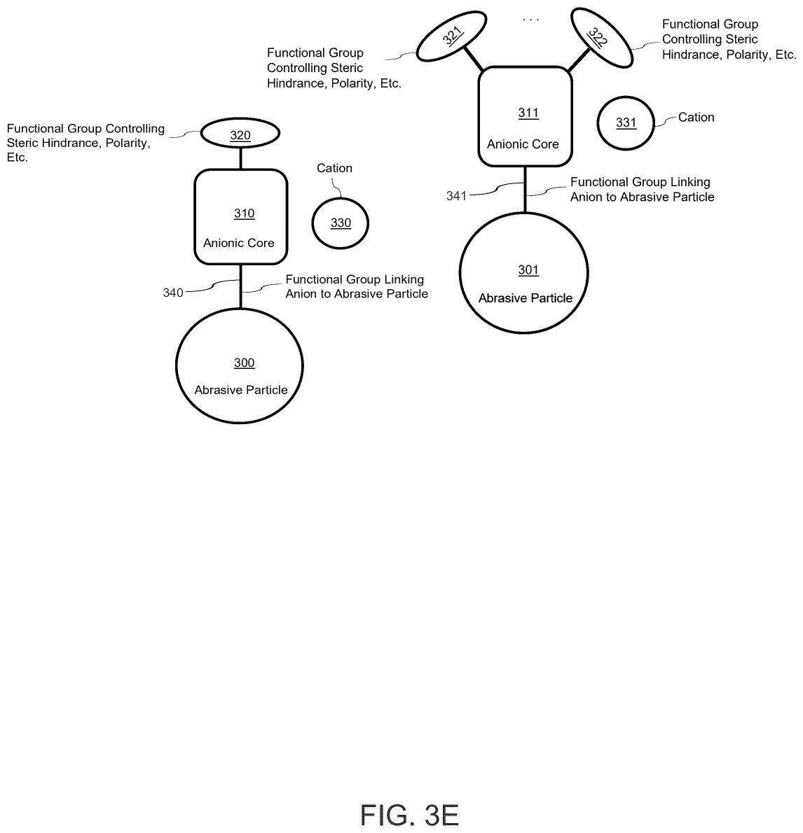

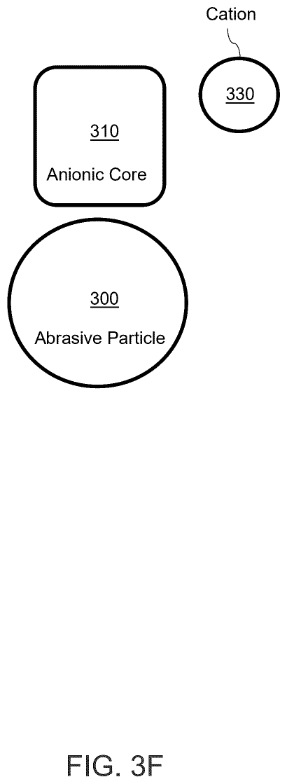

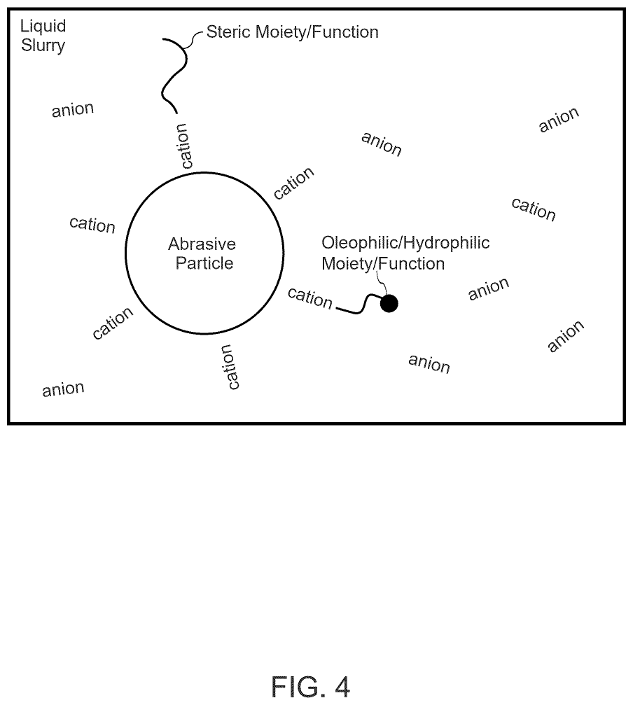

Of course, it should be understood that any abrasive particle within the slurry may be stabilized by multiple cations. For example, multiple cations may act together to surround each of the abrasive particles, enhancing their stability within the slurry. For simplicity, only one is shown in FIGS. 2 and 3. For example, FIG. 4 shows a diagram of an example embodiment where multiple cations surround an abrasive particle, while the anions move freely within the slurry free from the cations. Some cations may also move freely within the slurry and are not bonded to any abrasive particles. As shown in FIG. 4, some cations may have one type of functional group controlling steric hindrance, while other cations have a functional group controlling polarity, oleophilicity, hydrophilicity, solubility, affinity for the workpiece, etc. In some embodiments, the cationic core 210 comprises an aromatic ring. For example, the cationic core may comprise a heteroaryl group. Heteroaryl groups may include for example, nitrogen-containing heteroaryl groups or oxygen-containing heteroaryl groups.

Suitable cations containing nitrogen-containing heteroaryl groups include, for example, pyridinium-based cations, such as pyridinium, pyridazinium, pyramidinium, pyrazinium, quinolinium, isoquinolinium, and bipyridinium cations, as shown below.

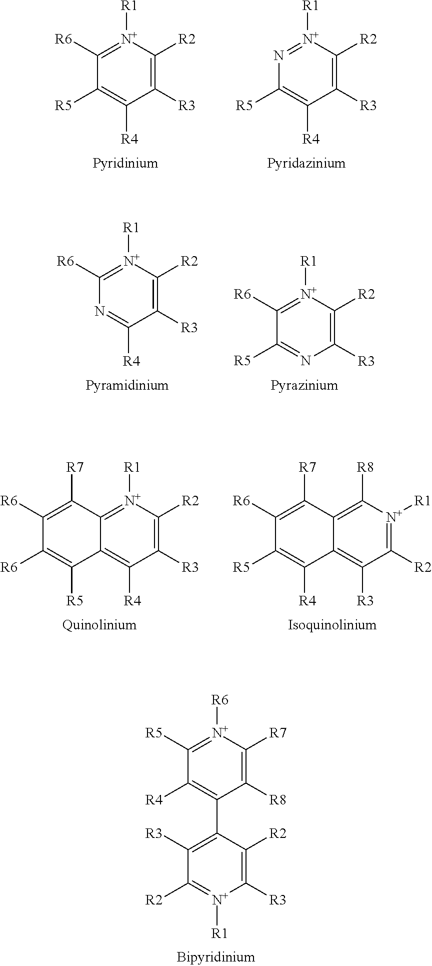

Other suitable cations containing nitrogen-containing heteroaryl groups include imidazolium-based cations, such as imidazolium, pyrazolium, 1,2,3-triazolium, 1,2,4-triazolium benzimidazolium, thiazolium, or oxazolium cations, as shown below.

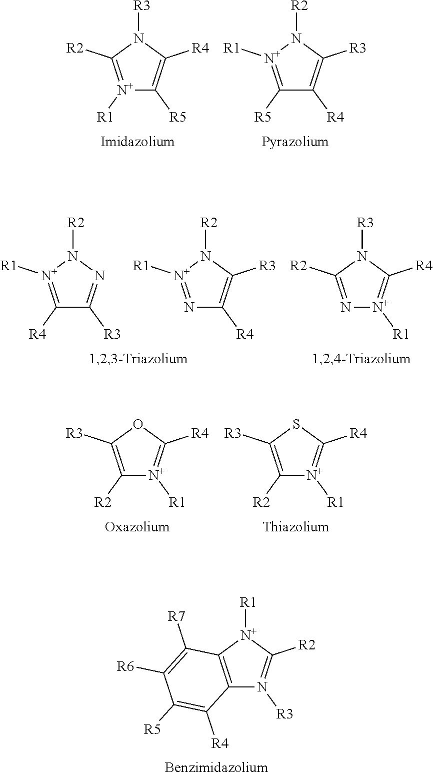

In some embodiments, the cationic core comprises an oxygen-containing heteroaryl group. For example, suitable oxygen-containing heteroaryl cations include oxonium cations such as pyrylium and benzopyrylium cations, as shown below.

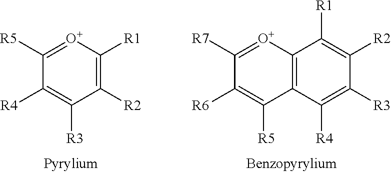

In some embodiments, the positive charge is not carried on an aromatic ring. For example, some suitable nitrogen-containing cations include quaternary ammonium ions. For example, in some embodiments, the cation contains a quaternary ammonium cation with an aryl substituent group. For example, in some embodiments, the quaternary ammonium cation may be a benzyl quaternary ammonium cation, as shown below.

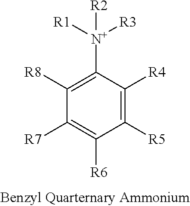

Other suitable nitrogen-containing cations include diazonium cations. For example, in some embodiments, the cation contains a diazonium cation with an aryl substituent group. For example, in some embodiments, the quaternary ammonium cation may be a benzyl diazonium cation, as shown below.

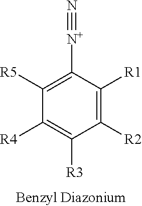

Other examples of cations in which the positive charge is not carried on an aromatic ring include phosphonium cations. For example, in some embodiments, the phosphonium cation may be a benzyl phosphonium cation, as shown below.

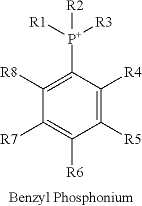

Other examples of cations in which the positive charge is not carried on an aromatic ring include sulfonium cations. For example, in some embodiments, the sulfonium cation may be a benzyl sulfonium cation, as shown below.

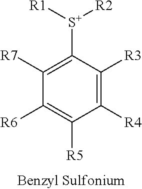

In some embodiments, the cation may be an organometallic compound, such as a ferrocenium cation, as shown below.

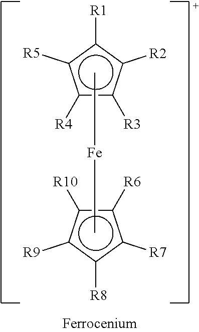

In the above formulas, R1-R10 can be, independently, hydrogen; a substituted or unsubstituted C₁-C₁₀ straight chain or branched alkyl group (e.g., methyl, ethyl, n-propyl, isopropyl, n-butyl, isobutyl, sec-butyl, tert-butyl, n-pentyl, etc.); a substituted or unsubstituted C₃-C₁₄ cycloalkyl group (e.g., adamantyl, cyclopropyl, cyclobutyl, cyclopentyl, cyclooctyl, cyclohexenyl, etc.); a substituted or unsubstituted C₁-C₁₀ alkenyl group (e.g., ethylene, propylene, 2-methypropylene, pentylene, etc.); a substituted or unsubstituted C₂-C₁₀ alkynyl group (e.g., ethynyl, propynyl, etc.); a substituted or unsubstituted C₁-C₁₀ alkoxy group (e.g., methoxy, ethoxy, n-propoxy, isopropoxy, n-butoxy, t-butoxy, sec-butoxy, n-pentoxy, etc.); a substituted or unsubstituted acyloxy group (e.g., methacryloxy, methacryloxyethyl, etc.); a substituted or unsubstituted aryl group (e.g., phenyl); a substituted or unsubstituted heteroaryl group (e.g., pyridyl, furanyl, thienyl, thiazolyl, isothiazolyl, triazolyl, imidazolyl, isoxazolyl, pyrrolyl, pyrazolyl, pyridazinyl, pyrimidinyl, quinolyl, etc.); a silyl group (e.g., represented by a chemical formula of —SiY₁₁Y₁₂Y₁₃, where Y₁₁, Y₁₂ and Y₁₃ may each be hydrogen, a substituted or unsubstituted alkyl group, a substituted or unsubstituted aryl group, or a substituted or unsubstituted alkoxy group, such as trimethylsilyl group, a triethylsilyl group, a trimethoxy silyl group, a triethoxy silyl group, etc.); an ether group (e.g., having the formula-O[(CH₂)ₐO]_{b}—X or the formula-CH₂O[(CH₂)ₐO]_{b}—X where a is an integer from 1-6, b is an integer from 1 to 100, and X is H, optionally substituted alkyl, or optionally substituted aryl, such as a poly(alkylene oxide), a cyclic ether, an arylether, or a polymer or copolymer thereof, etc.); a carboxyl group (e.g., a C₁₋₃₀ alkyl carboxyl group); an acyl group; an acylamino group (e.g., acetylamino); an amino group; an aryloxy group; a carboxyl ester group; a cycloalkyloxy group; a hydroxyl group (e.g., having the formula —OH or —R—OH, where R is a C₁-C₁₀ alkyl group); a halogen; a haloalkyl group; a heteroaryloxy group; a heterocyclyl group; a heterocycloxy group; and so forth.

In some embodiments, the cation comprises one of the structures shown above, and at least one of the R1-R10 groups is a first functional group configured to bond to an abrasive particle. For example, in some embodiments, the first functional group may comprise a silyl group, a hydroxyl group, a carboxyl group, or an amino group. However, any other functional group that can form a bond with the abrasive particle can also be used. The type of functional group used as the first functional group may be chosen based on the characteristics of the abrasive particle and the solution.

In the nitrogen-containing heteroaryl cations described above, such as pyridinium, pyridazinium, pyramidinium, pyrazinium, quinolinium, isoquinolinium, bipyridinium, imidazolium, pyrazolium, 1,2,3-triazolium, 1,2,4-triazolium, oxazolium, thiazolium, and benzimidazolium, the first functional group may be attached to the charge-carrying nitrogen or may be attached to another atom within the heteroaryl ring. For example, in any of such cations, R1 may contain the first functional group. In other embodiments, any one of R2-R10 may contain the first functional group. In some embodiments, the first functional group is located in the para position relative to the charge-carrying nitrogen. For example, in some embodiments, when the cation is a pyridinium, pyridazinium, pyramidinium, or quinolinium cation, R4 may contain the first functional group. In some embodiments, when the cation is a bipyridinium cation, either R1 or R6 may contain the first functional group.

In some embodiments, when the cation is imidazolium, pyrazolium, 1,2,3-triazolium, 1,2,4-triazolium, or benzimidazolium, the first functional group is attached to one of the non-charged nitrogen atoms. For example, if the cation is imidazolium, 1,2,4-triazolium, or benzimidazolium, the first functional group can be in the R3 position. Similarly, if the cation is pyrazolium or 1,2,3-triazolium, the first functional group can be in the R2 position.

In some embodiments, when the cation is oxazolium or thiazolium, the first functional group can be in the R3 position.

In some embodiments, when the cation is benzopyrylium, the first functional group can be in the R4 position.

In some embodiments, when the cation is a benzyl quaternary ammonium, benzyl diazonium, benzyl phosphonium, or benzyl sulfonium cation, the first functional group can be in the para position. For example, for the benzyl quaternary ammonium cation or the benzyl phosphonium cation, the first functional group may be in the R6 position. Similarly, for the benzyl diazonium cation, the first functional group may be in the R3 position. Similarly, for the benzyl sulfonium cation, the first functional group may be in the R5 position.

In some embodiments, the cation comprises one of the structures shown above, and at least one of the other R1-R10 groups is a second functional group. The second functional group may be optimized to control the stability of the abrasive particle and cation complex within the solution. For example, the second functional group may be selected to optimize polarity, steric hindrance, hydrophilicity, oleophilicity, solubility, and the like. In some embodiments, some cations may have a second functional group selected to control polarity while other cations may have a second functional group selected to provide steric hindrance.

In this regard, in some embodiments, the second functional group may be a polar group, such as a hydroxyl group (e.g., glycol group), an alkoxy group, an ether group, a carboxyl group, a carbonyl or an amino group. For example, a polar group may be used to improve solubility in water or another polar solvent. In some embodiments, the second functional group may be a non-polar functional group, such as an alkyl group (e.g., oily group), a cycloalkyl group, or an aryl group. For example, a non-polar functional group may be used to improve solubility in a non-polar solvent. In some embodiments, the second functional group may provide an optimal degree of steric hindrance. For example, it may be a bulky group, such as a branched chain alkyl group, a cycloalkyl group, or an aryl group. In some embodiments, the second functional group may provide affinity for a semiconductor workpiece. Such functional groups may include amine, hydroxyl, and aryl groups. However, it should be understood that the second functional group is not limited and may be any suitable functional group, such as any of the options listed above for R1-R10. The type of functional group desired for the second functional group may depend on the solvent, the pH of the solution, the type of abrasive used, and the type of anion used.

In the nitrogen-containing heteroaryl cations described above, such as pyridinium, pyridazinium, pyramidinium, pyrazinium, quinolinium, isoquinolinium, bipyridinium, imidazolium, pyrazolium, 1,2,3-triazolium, 1,2,4-triazolium, oxazolium, thiazolium, and benzimidazolium, the second functional group may be attached to the charge-carrying nitrogen or may be attached to another atom within the heteroaryl ring. For example, in any of such cations, R1 may contain the second functional group. In other embodiments, any one of R2-R10 may contain the second functional group. In some embodiments, the second functional group is located in the para position relative to the charge-carrying nitrogen. For example, when the cation is a pyridinium, pyridazinium, pyramidinium, or quinolinium cation, R4 may contain the second functional group. In some embodiments, when the cation is a bipyridinium cation, either R1 or R6 may contain the second functional group.

In some embodiments, when the cation is imidazolium, pyrazolium, 1,2,3-triazolium, 1,2,4-triazolium, benzimidazolium, oxazolium, or thiazolium, the second functional group is attached to the charged nitrogen atom. For example, if the cation is imidazolium, pyrazolium, 1,2,3-triazolium, 1,2,4-triazolium, benzimidazolium, oxazolium, or thiazolium, the second functional group can be in the R1 position.

In some embodiments, when the cation is benzopyrylium, the second functional group can be in the R1 position.

In some embodiments, when the cation is a benzyl quaternary ammonium, benzyl phosphonium, or benzyl sulfonium cation, the second functional group can be attached to the charge-carrying atom (e.g., N, P, or S). For example, for the benzyl quaternary ammonium cation or the benzyl phosphonium cation, the second functional group may be in the R1, R2, and/or R3 position. Similarly, for the benzyl sulfonium cation, the first functional group may be in the R1 and/or R2 position. It should be understood that more than one functional group in addition to the first functional group can be used. As such, the cations are not limited to having only a first functional group and a second functional group. For example, in the case of a benzyl quaternary ammonium or benzyl phosphonium cation, R1, R2, and R3 may all be functional groups, which can be the same or different from each other. Similarly, for the benzyl sulfonium cation, R1 and R2 may each be functional groups, which may be the same or different from each other.

For the benzyl diazonium cation, the second functional group may be in ortho position. For example, it may be in the R1 and/or R5 position. In some embodiments, both R1 and R5 are functional groups.

In one example embodiment, the cation is a pyridinium cation and the first functional group is in the R4 position and the second functional group is in the R1 position. The remaining R groups may be H or further functional groups.

In one example embodiment, the cation is a pyridinium cation and the first functional group is in the R1 position and the second functional group is in the R4 position. The remaining R groups may be H or further functional groups.

In one example embodiment, the cation is a quinolinium cation and the first functional group is in the R1 position and the second functional group is in the R4 position. The remaining R groups may be H or further functional groups.

In one example embodiment, the cation is a quinolinium cation and the first functional group is in the R4 position and the second functional group is in the R1 position. The remaining R groups may be H or further functional groups.

In one example embodiment, the cation is a bipyridinium cation and the first functional group is attached to one of the nitrogen atoms (i.e., in the R1 or R6 position) and the second functional group is attached to the other nitrogen atom (i.e., in R1 or R6 position, whichever the first functional group is not attached to). The remaining R groups may be H or further functional groups.

In one example embodiment, the cation is an imidazolium cation and the first functional group is in the R3 position and the second functional group is in the R1 position. The remaining R groups may be H or further functional groups.

In one example embodiment, the cation is a benzimidazolium cation and the first functional group is the in R3 position and the second functional group is in the R1 position. The remaining R groups may be H or further functional groups.

In one example embodiment, the cation is a 1,2,4-triazolium cation and the first functional group is in the R3 position and the second functional group is in the R1 position. The remaining R groups may be H or further functional groups.

In one example embodiment, the cation is a thiazolium cation and the first functional group is in the R3 position and the second functional group is in the R1 position. The remaining R groups may be H or further functional groups.

In one example embodiment, the cation is an oxazolium cation and the first functional group is in the R3 position and the second functional group is in the R1 position. The remaining R groups may be H or further functional groups.

In one example embodiment, the cation is a benzyl quaternary ammonium cation and the first functional group is in the R6 position and the second functional group is in the R1, R2, and R3 positions. The remaining R groups may be H or further functional groups.

In one example embodiment, the cation is a benzyl diazonium cation and the first functional group is in the R3 position and the second functional group is in the R1 and R5 positions. The remaining R groups may be H or further functional groups.

In one example embodiment, the cation is a benzopyrylium cation and the first functional group is in the R3 position and the second functional group is in the R1 position. The remaining R groups may be H or further functional groups.

In one example embodiment, the cation is a benzyl phosphonium cation and the first functional group is in the R6 position and the second functional group is in the R1, R2, and R3 positions. The remaining R groups may be H or further functional groups.

In one example embodiment, the cation is a benzyl sulfonium cation and the first functional group is in the R5 position and the second functional group is in the R1 and R2 positions. The remaining R groups may be H or further functional groups.

In one example embodiment, the cation is a ferrocenium cation and the first functional group is in any of the R1-R5 positions and the second functional group is in any of the R6-R10 positions. The remaining R groups may be H or further functional groups.

In some example embodiments, the cationic core is selected from any of the cations described above and R1-R10 are all H. In other example embodiments, the cationic core is selected from any of the cations described above and one of R1-R10 is the first functional group (i.e., configured to bond to an abrasive particle) and all the other R groups are H. In other example embodiments, the cationic core is selected from any of the cations described above and one of R1-R10 is the second functional group (i.e., configured to provide stability within the slurry and/or affinity for the workpiece) and all the other R groups are H.

The anion can be selectively chosen to optimize solubility and electrolytic function. For example, in some embodiments, the anion is chosen so that the ionic compound (i.e., including the cation and anion) is soluble in the solvent. In some embodiments, the anion is a small anion to better facilitate penetration of the semiconductor workpiece to optimize the electrochemical reaction at the surface. For example, in some embodiments, the anion is selected from a chloride, fluoride, iodide, bromide, nitrate, or nitrite. In other emobidments, the anion may include tetrafluoroborate, hexafluorophosphate, hexafluoroantimonate, tetra-phenylborate, trifluoromethanesulfonate, nonaflate, bis(trifluoromethylsulfonyl)imide, methylsulfate, acetate, and fluoroacetate anions. When the cation is ferrocenium, the anion may be a suitable counterion such as tetra-fluoroborate, hexafluorophosphate, hexafluoroantimonate, or tetra-phenylborate.

In some embodiments, the ionic compound may be an ionic liquid, as described above. Examples of ionic liquids include, for example, methyl-octyl-imidazolium-chloride and butyl-methyl-imidazolium-bis-trifluoromethane-sulfonimide. However, it should be understood that many of the cations described above can be paired with suitable anions resulting in a low melting salt (i.e., an ionic liquid), particularly those containing imidazolium and pyridinium cations. In other embodiments, the cationic compound is a solid at ambient conditions.

In other embodiments, the anion may be bonded to the abrasive particle and the cation may be free within the slurry. Such embodiments may be employed when there is a desire to reduce a component of the system (e.g., SiO₂). In such embodiments, the anion may contain an anion core, a first functional group configured to bond to the abrasive particle, and a second functional group configured to provide steric hindrance, solubility, hydrophilicity, oleophilicity, affinity for the workpiece, etc.

FIG. 3A shows a diagram of various components within the slurry when an anion is selected to stabilize the abrasive particle. For example, it can be seen that an anionic core 310 is bonded to an abrasive particle 300 by a first functional group 340 attached to the anionic core 310. A second functional group 320 is also attached to the anionic core 310. The second functional group can be tailored for stability within the solvent. For example, the second functional group can be selected to enhance solubility, polarity, and/or provide optimal steric hindrance. The second functional group may also be selected for affinity to the semiconductor workpiece to promote interaction between the abrasive particle and the surface of the workpiece. A cation 330 is also shown. The cation 330 and anion (containing anionic core 310, first functional group 340 and second functional group 320) are free from each other within the solution. The cation may be selected for optimal electrolytic activity and reduction potential. The various components of the slurry are explained in further detail below.

As shown in FIG. 3A, the first functional group 340 can be configured to bond to the abrasive particle 300. The second functional group 320 can be configured to control the stability of the anion within the solvent and/or affinity for the workpiece. As the anions within the slurry are dissolved in the solvent and linked to the abrasive particles, they stabilize the abrasive particles within the slurry (e.g., keep them suspended within the slurry).

The anion is not limited to having only two functional groups. For example, as shown in FIG. 3B, the anion may contain a first functional group 340 linking the anion to the abrasive particle 300 and multiple additional functional groups 320, which may each be selected to provide stability within the slurry. For example, the additional functional groups 320 may be selected to provide steric hindrance, solubility, hydrophilicity, oleophilicity, affinity for the workpiece, etc.

The additional functional groups may be the same or different from each other. For example, FIG. 3B shows an example embodiment in which the anion contains multiple functional groups 320 controlling steric hindrance, polarity, etc. that are the same as each other. FIG. 3C, on the other hand, shows an example embodiment in which the anion contains multiple functional groups 320 and 321 controlling steric hindrance, polarity, etc. that are different from each other. It should be understood that, as indicated by the ellipsis in FIGS. 3A and 3B, more than two functional groups in addition to the first functional group 340 may be attached to the anionic core. Any further functional groups may be the same as or different from functional groups 320 or 321.

Further, as shown in FIG. 3D, not all abrasive particles in the slurry are necessarily bonded to an anion. For example, in FIG. 3D, abrasive particle 300 is stabilized by an anion, while abrasive particle 301 is not stabilized by an anion. Abrasive particles 300 and 301 may be formed from the same or different materials.

Furthermore, as shown in FIG. 3E, multiple different types of anions may be included in the slurry. For example, FIG. 3E shows an example embodiment in which an abrasive particle 300 is stabilized by an anion containing an anionic core 310, a first functional group 340 linking the anionic core to the abrasive particle 300, and a second functional group 320. The slurry also contains an abrasive particle 301 stabilized by an anion containing an anionic core 311, a first functional group 341 linking the anionic core to the abrasive particle 301, and two additional functional groups 321 and 322. The slurry also contains cations 330 and 331. The abrasive particles 300 and 301 may be formed from the same or different materials, the anionic cores 310 and 311 may be the same as or different from each other, the first functional groups 340 and 341 may be the same as or different from each other, the additional functional groups 320, 321, and 322, may be the same as or different from each other, and the cations 330 and 331 may be the same as or different from each other.

In other embodiments, as shown in FIG. 3F, the anion may not contain a functional group bonding the anionic core 310 to the abrasive particle 300. In such embodiments, the anion may be bonded to the abrasive particle 300 through non-covalent means, such as electrostatic forces or ion-dipole interactions. In such embodiments, the abrasive particle may have a positive surface charge. For example, in some embodiments, the abrasive particle may have basic groups (e.g., amino groups) at its surface, which can be protonated in the slurry to provide the positively charged surface. The anion, having a negative charge, may then be bonded to the abrasive particle by an electrostatic force. In other embodiments, the abrasive particle may have polar groups on its surface and the anion may be bonded to the particle by an ion-dipole interaction.

In some embodiments, as shown in FIG. 2F, the anion may not contain any functional groups attached to the ionic core to provide stability (e.g., 320, 321, 322 in FIGS. 3A-3E). In such embodiments, the particles may be stabilized through electrostatic repulsion forces (e.g., a sufficient zeta potential) between particles, preventing them from flocculating. For example, anions may surround the abrasive particles within the slurry effectively creating a negatively charged surface layer containing the negatively charged anions. The negatively charged surface layers of the abrasive particles act to repel each other to maintain stability in the solution.

In some embodiments, as shown in FIG. 3F, the anion may not contain any functional groups attached to the anionic core. In other embodiments, the anion may contain a functional group configured to bond to the abrasive particle (e.g., 340 in FIGS. 3A-3E) but no other functional groups (e.g., 320, 321, 322 in FIGS. 3A-3E). In other embodiments, the anion may contain a functional group configured to provide stability within the solution (e.g., 320, 321, 322 in FIGS. 3A-3E) but no functional group configured to bond to the abrasive particle (e.g., 340 in FIGS. 3A-3E).

Of course, it should be understood that any abrasive particle within the slurry may be stabilized by multiple anions. For example, multiple anions may act together to surround each of the abrasive particles, enhancing their stability within the slurry. Some anions may also move freely within the slurry and are not bonded to any abrasive particles.

In some embodiments, the anionic core comprises an aromatic ring. Suitable anions include, for example, benzenesulfonate anions, as shown below.

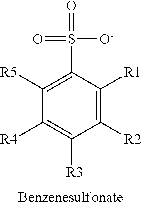

In the above formula, R1-R5 can be, independently, hydrogen; a substituted or unsubstituted C₁-C₁₀ straight chain or branched alkyl group (e.g., methyl, ethyl, n-propyl, isopropyl, n-butyl, isobutyl, sec-butyl, tert-butyl, n-pentyl, etc.); a substituted or unsubstituted C₃-C₁₄ cycloalkyl group (e.g., adamantyl, cyclopropyl, cyclobutyl, cyclopentyl, cyclooctyl, cyclohexenyl, etc.); a substituted or unsubstituted C₁-C₁₀ alkenyl group (e.g., ethylene, propylene, 2-methypropylene, pentylene, etc.); a substituted or unsubstituted C₂-C₁₀ alkynyl group (e.g., ethynyl, propynyl, etc.); a substituted or unsubstituted C₁-C₁₀ alkoxy group (e.g., methoxy, ethoxy, n-propoxy, isopropoxy, n-butoxy, t-butoxy, sec-butoxy, n-pentoxy, etc.); a substituted or unsubstituted acyloxy group (e.g., methacryloxy, methacryloxyethyl, etc.); a substituted or unsubstituted aryl group (e.g., phenyl); a substituted or unsubstituted heteroaryl group (e.g., pyridyl, furanyl, thienyl, thiazolyl, isothiazolyl, triazolyl, imidazolyl, isoxazolyl, pyrrolyl, pyrazolyl, pyridazinyl, pyrimidinyl, quinolyl, etc.); a silyl group (e.g., represented by a chemical formula of —SiY₁₁Y₁₂Y₁₃, where Y₁₁, Y₁₂ and Y₁₃ may each be hydrogen, a substituted or unsubstituted alkyl group, a substituted or unsubstituted aryl group, or a substituted or unsubstituted alkoxy group, such as trimethylsilyl group, a triethylsilyl group, a trimethoxy silyl group, a triethoxy silyl group, etc.); an ether group (e.g., having the formula —O[(CH₂)ₐO]_{b}—X or the formula —CH₂O[(CH₂)O]_{b}—X where a is an integer from 1-6, b is an integer from 1 to 100, and X is H, optionally substituted alkyl, or optionally substituted aryl, such as a poly(alkylene oxide), a cyclic ether, an arylether, or a polymer or copolymer thereof, etc.); a carboxyl group (e.g., a C₁₋₃₀ alkyl carboxyl group); an acyl group; an acylamino group (e.g., acetylamino); an amino group; an aryloxy group; a carboxyl ester group; a cycloalkyloxy group; a hydroxyl group (e.g., having the formula —OH or —R—OH, where R is a C₁-C₁₀ alkyl group); a halogen; a haloalkyl group; a heteroaryloxy group; a heterocyclyl group; a heterocycloxy group; and so forth.

One of R1-R5 may comprise the first functional group and another one of R1-R5 may be the second functional group. The first and second functional groups may be selected from the same functional groups described above with respect to cations. In one example embodiment, R1 or R2 may be the first functional group and R4 or R5 may be the second functional group. The other R groups may be H or may be an additional functional group.

In some example embodiments, R1-R5 are all H. In other example embodiments, one of R1-R5 is the first functional group (i.e., configured to bond to an abrasive particle) and all the other R groups are H. In other example embodiments, one of R1-R5 is the second functional group (i.e., configured to provide stability within the slurry and/or affinity for the workpiece) and all the other R groups are H.

In embodiments where the anion is bonded to the abrasive particle, the cation may be an alkali metal such as sodium, potassium, lithium, etc., ammonium, or any of the cations described herein.

The ionic compound may be present in the slurry in an amount from about 0.1 wt. % or more, such as about 0.5 wt. % or more, such as about 1 wt. % or more, such as about 1.5 wt. % of more. The ionic compound may be present in the slurry in an amount of about 5 wt. % or less, such as about 4 wt. % or less, such about 3 wt. % or less, such as about 2 wt. % or less, such as about 1.5 wt. % or less. For example, in some embodiments, the concentration of the ionic compound within the slurry may be from about 1 wt. % to about 2 wt. %.

The pH of the slurry may be adjusted as desired. For example, in some embodiments, the pH of the slurry is about 1 or more, such as about 2 or more, such as about 3 or more, such as about 4 or more, such as about 5 or more, such as about 6 or more, such as about 7 or more, such as about 8 or more, such as about 9 or more. The pH of the slurry may be about 13 or less, such as about 12 or less, such as about 11 or less, such as about 10 or less, such as about 9 or less, such as about 8 or less, such as about 7 or less, such as about 6 or less, such as about 5 or less, such as about 4 or less, such as about 3 or less. For example, in some embodiments, the pH can be from about 2 to about 10. In some embodiments, the pH may be relatively high (i.e., basic), such as from about 7 to about 10. In other embodiments, the pH may be relatively low (i.e., acidic), such as from about 2-7. When the pH is relatively high, cationic particles may be used to stabilize the abrasive particles as the abrasive particles tend to have a negative surface charge. The system described herein may have advantages over slurries using strong oxidizers, which typically have very low pH values, which can reduce the effectiveness of the abrasive particles.

In this regard, pH adjusting agents may be provided to the slurry to modify the pH to the desired level. pH adjusting agents include acids, bases, and buffers, which are all well known in the art. For example, one or more of ammonium hydroxide, potassium hydroxide, nitric acid, ammonium acetate, and disodium citrate may be used to control the pH of the slurry.

In some embodiments, to further stabilize the particles in the solution, a surfactant may be included in the slurry. For example, the surfactant may be an ionic surfactant, such as a cationic surfactant, an anionic surfactant, or a zwitterionic surfactant. Examples of cationic surfactants may include, for example, fatty amine salts, quaternary ammonium salts, salts of fatty amine ethoxylates, quaternized fatty amine ethoxylates, and mixtures thereof. Suitable counterions (i.e., anions) may include chloride, fluoride, iodide, bromide, sulfate, tosylate, acetate, phosphate, nitrate, sulfonate, carboxylate, and the like. Anionic surfactants include, for example, alkyl sulfates, alkyl ether sulfates, alkyl glyceryl ether sulfonates, hydroxyalkyl sulfonates, and the like. Suitable counterions (i.e., cations) include, for example, sodium, potassium, ammonium, alkylamines, alkoxyamines, and the like. Zwitterionic surfactants include, for example, betaines, sulfobetaines, and amine oxides, such as cocamidopropyl betaine, lauryl hydroxysultaine, lauryl dimethylamine oxide, and the like.

In some embodiments, an additional salt is added to the slurry to increase the electrolyte concentration. Such additional salts may include, for example, NaCl, NaNO₃, NaF, KCl, KNO₃, KF, NH₄Cl, NH₄NO₃, NH₄F, and combinations thereof.

In some embodiments, a complexing and/or chelating agent may also be contained in the slurry. Suitable complexing and/or chelating agents include, for example, amides and amines (e.g., bis(trimethylsilylamide) tetramer), β-diketonate compounds (e.g., 1,1,1,5,5,5-hexafluoro-2,4-pentanedione, acetylacetonate, 1,1,1-trifluoro-2,4-pentanedione), carboxylates (e.g., formate, acetate, long chain carboxylates), amino acids, organic acids (e.g., citric acid, acetic acid, oxalic acid, maleic acid, malonic acid, succinic acid, phosphinic acid, uric acid), phosphonic acid derivatives (e.g., hydroxyethylidene diphosphonic acid, nitrilo-tris(methylenephosphonic acid), 1-hydroxyethane-1,1-diphosphonic acid), ethylenediaminetetraacetic acid (EDTA), nitrilotriacetic acid (NTA), diethylenetriaminepentaacetic acid (DTPA), hydroxyethylethylenediaminetriacetic acid (HEDTA), ethylenediamine-N,N′-disuccinic acid (EDDS), iminodisuccinic acid (IDS), 1,3-diaminopropane-N,N,N′,N′-tetraacetic acid (PDTA), triethylenetetraminehexaacetic acid (TTHA), N-(2-hydroxyethyl)ethylenediaminetriacetic acid (HEDTA), diethylenetriaminepentamethylenephosphonic acid (DTPMP), nitrilotris(methylenephosphonic acid) (NTMP), ethylenediaminetetra(methylenephosphonic acid) (EDTMP), 1,2-diaminocyclohexanetetraacetic acid (DCTA), and the like.

In some embodiments, the slurry is free of strong oxidizers, such as permanganate compounds. As described above, such compounds can create environmental and safety concerns and can reduce the effectiveness of the abrasive particles. Advantageously, polishing can be conducted without such compounds using the slurries and ECMP methods described herein.

In some embodiments, the abrasive particle itself may be cationic. In such embodiments, it may not be necessary to include additional cations in the slurry. As an example, the cationic abrasive particle may include any of the abrasives described above to which a treatment or modification has been applied to create a positively charged surface. For example, in some embodiments, a cationic abrasive can be formed by attaching cationic groups to the abrasive particle surface by adsorption or through the use of a coupling agent, as is known in the art.

In this regard, in some embodiments, the slurry comprises a solvent, a cationic abrasive particle, and an anion. The anion may be provided to the slurry by dissolving a salt, such as NaCl, NaNO₃, NaF, KCl, KNO₃, KF, NH₄Cl, NH₄NO₃, NH₄F, or combinations thereof into the solvent.

When the slurry contains cationic abrasive particles, the slurry may be relatively acidic, such as having a pH from about 2 to about 7, so that the pH remains below the isoelectric point of the abrasive. However, it should be understood that the pH of slurry will depend on the nature of the abrasive particle and the slurry may have any pH such that the abrasive particle is cationic.

In some embodiments, the abrasive particle itself may be anionic. In such embodiments, it may not be necessary to include additional anions in the slurry. As an example, the anionic abrasive particle may include any of the abrasives described above to which a treatment or modification has been applied to create a negatively charged surface. For example, in some embodiments, an anionic abrasive can be formed by attaching anionic groups to the abrasive particle surface by adsorption or through the use of a coupling agent, as is known in the art.

In this regard, in some embodiments, the slurry comprises a solvent, an anionic abrasive particle, and a cation The cation may be provided to the slurry by dissolving a salt, such as NaCl, NaNO₃, NaF, KCl, KNO₃, KF, NH₄Cl, NH₄NO₃, NH₄F, or combinations thereof into the solvent.

When the slurry contains anionic abrasive particles, the slurry may be relatively basic, such as having a pH from about 7 to about 10, so that the pH remains above the isoelectric point of the abrasive. However, it should be understood that the pH of slurry will depend on the nature of the abrasive particle and the slurry may have any pH such that the abrasive particle is anionic.

FIG. 4 depicts a flow chart of an example method 1000 according to example embodiments of the present disclosure. The method 1000 includes a method for polishing the surface of a workpiece. The method 1000 may be implemented, for instance, using the polishing system 100 of FIG. 1 and the slurry described herein. The method 1000 depicts operations performed in a particular order for purposes of illustration and discussion. Those of ordinary skill in the art, using the disclosures provided herein, will understand that the operations of any of the methods described herein may be adapted, expanded, performed simultaneously, omitted, rearranged, include steps not illustrated, and/or modified in various ways without deviating from the scope of the present disclosure.

At 1010, the method 1000 may include providing the surface of a workpiece on a polishing pad. For instance, a workpiece may be on a workpiece support and the workpiece may be operable to provide a surface of the workpiece to the polishing pad. In some embodiments, the polishing pad may be on a platen of an electrochemical mechanical polishing (ECMP) system. The workpiece may include silicon carbide. For example, the workpiece may be a semiconductor workpiece such as a silicon carbide semiconductor workpiece (e.g., wafer).

At 1020, the method 1000 may include providing the slurry described herein onto a surface of the polishing pad. For instance, the polishing system may include a delivery system with one or more outlets. The delivery system may deliver the slurry to the polishing pad. As described herein, the slurry includes an electrolyte solution such that electrolytes are delivered to polishing pad.

The structure and composition of the polishing pad may allow the electrolyte to disperse throughout the polishing pad. For instance, the polishing pad may include one or more conductive structure to provide an electrically conductive path through the polishing pad.

At 1030 the method 1000 may include providing a bias between the workpiece and the electrolyte through an electrically conductive path for charge carriers extending through the polishing pad. For instance, the polishing system may include an electrode that is operable to provide a bias voltage or a bias current to the electrolytes of the slurry delivered to the polishing pad. The polishing pad is operable to provide an electrically conductive path for one or more charge carriers (e.g., of the electrolytes) through the polishing pad to a bias source. For example, the electrically conductive path through the polishing pad may include the one or more apertures (e.g., pores, perforations) operable to accommodate the electrolyte in the polishing pad and/or the electrically conductive path may include one or more conductive structures in the polishing pad.

A bias voltage or a bias current may be applied (e.g., via a workpiece electrode) between the wafer and the polishing pad to drive electrochemical reactions to occur at the surface of the workpiece, leading to material dissolution. The slurry applied between the workpiece and the polishing pad facilitates the electrochemical reactions (e.g., oxidation or reduction processes), carries away removed material, and provides lubrication for the mechanical polishing action, as in 1040.

The electrically conductive path to the bias source may be implemented in a variety of manners. For example, an electrically conductive support layer may be on the polishing pad and the electrically conductive path may be at least partially through the electrically conductive support layer (e.g., to the bias source). In another example, the polishing pad is on a platen and an adhesive layer is positioned between the polishing pad and the platen. The electrically conductive path is at least partially through the adhesive layer (e.g., to the bias source). In some examples, the electrically conductive path is at least partially through the platen.

For ECMP, while the electrochemical reactions are occurring, mechanical forces may be applied to the workpiece through the polishing pad. At 1040, the method 1000 may include imparting relative motion between the platen and the workpiece. For instance, the platen may be rotated about a first axis causing relative motion between the polishing pad and the workpiece. In some embodiments, the workpiece may be rotated about a second axis imparting relative motion between the polishing pad and the workpiece. In some examples, the second axis may be different from the first axis.

Relative motion between the workpiece and the polishing pad can facilitate the gradual removal of material from the surface of the workpiece. This can occur due to one or more abrasive elements (e.g., abrasive particles), for instance, provided as part of the slurry. In some examples, the polishing pad may include an abrasive containing material, as described herein.

The method 1000 may continue until the ECMP of the surface of the workpiece is complete. Determining when ECMP for a particular workpiece is complete may depend on one or more factors, including the specific requirements of the manufacturing process and the desired outcome for the workpiece surface. For instance, the method 1000 may continue until the desired thickness and uniformity of the workpiece is achieved. Additionally, or alternatively, the method 1000 may continue until a desired level of surface roughness is achieved. The surface roughness may be measured, for example, in terms of surface roughness parameters such as Sa (areal average roughness) or Sz (sum of the largest peak height value and the largest pit depth value). Additionally, or alternatively, the rate at which material (e.g., silicon carbide) is removed during the method 1000 may be monitored. The ECMP may be considered complete once a desired amount of material has been removed or a threshold amount of time has lapsed.

In some examples, visual inspection of the workpiece may provide an indication on the progress of the ECMP provided via method 1000. In some examples, computer vision or optical inspection coupled with machine learning algorithms may provide an indication on the progress of ECMP provided via the method 1000.

In some examples, the completeness of the method 1000 may be based on endpoint detection and/or the monitoring of other process parameters. For example, the polishing system (or operators thereof) implementing method 1000 may be configured to monitor parameters such as slurry resistivity, optical properties, electrical current, voltage, or chemical signals to detect changes associated with the removal of material from the workpiece surface. Additionally, or alternatively, the polishing system may monitor temperature, pressure, and electrolyte flow rate to help ensure that ECMP is proceeding as intended. Deviations from the expected process conditions may indicate completion or potential issues with the process.

Example aspects of the present disclosure are set forth below. Any of the below features or examples may be used in combination with any of the embodiments or features provided in the present disclosure.

In an aspect, the present disclosure provides an example slurry. In some implementations, the example slurry includes a solvent. In some implementations, the example slurry includes an abrasive particle. In some implementations, the example slurry includes an ionic compound comprising a cation and an anion, wherein one or more of the cation or anion is bonded to the abrasive particle.

In some implementations of the example slurry, the abrasive particle includes i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide, or a combination thereof.

In some implementations of the example slurry, the metal oxide includes alumina, ceria, zirconia, silica, or a combination thereof.

In some implementations of the example slurry, the solvent includes an organic solvent.

In some implementations of the example slurry, the solvent includes water.

In some implementations of the example slurry, the cation includes an aromatic ring.

In some implementations of the example slurry, the cation includes a nitrogen-containing cation.

In some implementations of the example slurry, the nitrogen containing cation includes a pyridinium, quinolinium, or bipyridinium cation.

In some implementations of the example slurry, the nitrogen-containing cation includes an imidazolium, benzimidazolium, triazolium, thiazolium, or oxazolium cation.

In some implementations of the example slurry, the nitrogen-containing cation includes a quaternary ammonium cation.

In some implementations of the example slurry, the quaternary ammonium cation includes a benzyl trialkylammonium cation.

In some implementations of the example slurry, the nitrogen containing cation includes a diazonium cation.

In some implementations of the example slurry, the diazonium cation includes a benzyl diazonium cation.

In some implementations of the example slurry, the cation includes an oxonium cation.

In some implementations of the example slurry, the oxonium cation includes a pyrylium or benzopyrylium cation.

In some implementations of the example slurry, the cation includes a phosphonium cation.

In some implementations of the example slurry, the phosphonium cation includes a benzyl phosphonium cation.

In some implementations of the example slurry, the cation includes a sulfonium cation.

In some implementations of the example slurry, the sulfonium cation includes a benzyl sulfonium cation.

In some implementations of the example slurry, the anion includes a chloride, nitrate, or fluoride anion.

In some implementations of the example slurry, the cation includes a ferrocenium cation.

In some implementations of the example slurry, the ionic compound includes an ionic liquid.

In some implementations of the example slurry, the cation includes a first functional group bonded to the abrasive particle.

In some implementations of the example slurry, the first functional group includes a silyl group or a hydroxyl group.

In some implementations of the example slurry, the cation includes a second functional group.

In some implementations of the example slurry, the second functional group includes an alkyl group, an aryl group, an ether group, a hydroxyl group, or a carboxyl group.

In some implementations of the example slurry, the pH of the slurry is from about 2 to about 10.

In some implementations of the example slurry, abrasive particles constitute from about 0.01 wt. % to about 5 wt. % of the slurry.

In some implementations of the example slurry, the ionic compound constitutes from about 1 wt. % to about 2 wt. % of the slurry.

In some implementations, the slurry comprises a surfactant.

In some implementations of the example slurry, the surfactant is a cationic surfactant, an anionic surfactant, or a zwitterionic surfactant.

In some implementations, the slurry comprises a salt.

In some implementations of the example slurry, the salt includes NaCl, NaNO₃, NaF, KCl, KNO₃, KF, NH₄Cl, NH₄NO₃, NH₄F, or a combination thereof.

In some implementations of the example slurry, the slurry is free of permanganate compounds.

In some implementation, the slurry comprises a basic compound.

In some implementations of the example slurry, the basic compound includes KOH.

In some implementations of the example slurry, the abrasive particle has a particle size from about 1 nm to about 1000 nm.

In an aspect, the present disclosure provides an example polishing system. In some implementations, the example polishing system includes a platen operable to rotate about an axis. In some implementations, the example polishing system includes a polishing pad on the platen. In some implementations, the example polishing system includes a bias source. In some implementations, the example polishing system includes a workpiece carrier operable to bring the semiconductor workpiece into contact with the polishing pad. In some implementations, the example polishing system includes a slurry comprising a solvent, an abrasive particle, and an ionic compound comprising a cation and an anion, wherein one or more of the cation or anion is bonded to the abrasive particle.

In some implementations, the system includes a delivery system operable to deliver the slurry to the polishing pad, the bias source operable to provide a bias between the semiconductor workpiece and the slurry.

In some implementations of the example polishing system, the bias source is electrically coupled to the slurry through an electrically conductive path through the polishing pad.

In some implementations of the example polishing system, the polishing pad includes an abrasive containing surface.

In some implementations of the example polishing system, the polishing system includes an electrochemical mechanical polishing (ECMP) system.

In some implementations of the example polishing system, the semiconductor workpiece includes silicon carbide (SiC).

In some implementations of the example polishing system, the abrasive particle includes i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide, or a combination thereof.

In some implementations of the example polishing system, the metal oxide includes alumina, ceria, zirconia, silica, or a combination thereof.

In some implementations of the example polishing system, the solvent includes an organic solvent.

In some implementations of the example polishing system, the solvent includes water.

In some implementations of the example polishing system, the cation includes an aromatic ring.

In some implementations of the example polishing system, the cation includes a nitrogen-containing cation.

In some implementations of the example polishing system, the nitrogen containing cation includes a pyridinium, quinolinium, or bipyridinium cation.

In some implementations of the example polishing system, the nitrogen-containing cation includes an imidazolium, benzimidazolium, triazolium, thiazolium, or oxazolium cation.

In some implementations of the example polishing system, the nitrogen-containing cation includes a quaternary ammonium cation.

In some implementations of the example polishing system, the quaternary ammonium cation includes a benzyl trialkylammonium cation.

In some implementations of the example polishing system, the nitrogen containing cation includes a diazonium cation.

In some implementations of the example polishing system, the diazonium cation includes a benzyl diazonium cation.

In some implementations of the example polishing system, the cation includes an oxonium cation.

In some implementations of the example polishing system, the oxonium cation includes a pyrylium or benzopyrylium cation.

In some implementations of the example polishing system, the cation includes a phosphonium cation.

In some implementations of the example polishing system, the phosphonium cation includes a benzyl phosphonium cation.

In some implementations of the example polishing system, the cation includes a sulfonium cation.

In some implementations of the example polishing system, the sulfonium cation includes a benzyl sulfonium cation.

In some implementations of the example polishing system, the anion includes a chloride, nitrate, or fluoride anion.

In some implementations of the example polishing system, the cation includes a ferrocenium cation.

In some implementations of the example polishing system, the ionic compound includes an ionic liquid.

In some implementations of the example polishing system, the cation includes a first functional group bonded to the abrasive particle.

In some implementations of the example polishing system, the first functional group includes a silyl group or a hydroxyl group.

In some implementations of the example polishing system, the cation includes a second functional group.

In some implementations of the example polishing system, the second functional group includes an alkyl group, an aryl group, an ether group, a hydroxyl group, or a carboxyl group.

In some implementations of the example polishing system, the pH of the slurry is from about 2 to about 10.

In some implementations of the example polishing system, abrasive particles constitute from about 0.01 wt. % to about 5 wt. % of the slurry.

In some implementations of the example polishing system, the ionic compound constitutes from about 1 wt. % to about 2 wt. % of the slurry.

In some implementations of the example polishing system, the slurry further includes a surfactant.

In some implementations of the example polishing system, the surfactant is a cationic surfactant, an anionic surfactant, or a zwitterionic surfactant.

In some implementations of the example polishing system, the slurry further includes a salt.

In some implementations of the example polishing system, the salt includes NaCl, NaNO₃, NaF, KCl, KNO₃, KF, NH₄Cl, NH₄NO₃, NH₄F, or a combination thereof.

In some implementations of the example polishing system, the slurry is free of permanganate compounds.

In some implementations of the example polishing system, the slurry further includes a basic compound.

In some implementations of the example polishing system, the basic compound includes KOH.

In an aspect, the present disclosure provides an example polishing system. In some implementations, the example polishing system includes a platen operable to rotate about an axis. In some implementations, the example polishing system includes a polishing pad on the platen. In some implementations, the example polishing system includes a bias source. In some implementations, the example polishing system includes a workpiece carrier operable to bring the semiconductor workpiece into contact with the polishing pad. In some implementations, the example polishing system includes a slurry comprising a solvent, a cationic abrasive particle, and an anion.

In some implementations of the example polishing system, the cationic abrasive particle includes i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide, or a combination thereof.

In some implementations of the example polishing system, the metal oxide includes alumina, ceria, zirconia, silica, or a combination thereof.

In some implementations of the example polishing system, the pH of the slurry is from about 2 to about 7.

In some implementations, the system includes a delivery system operable to deliver the slurry to the polishing pad, the bias source operable to provide a bias between the semiconductor workpiece and the slurry.

In some implementations of the example polishing system, the bias source is electrically coupled to the slurry through an electrically conductive path through the polishing pad.

In some implementations of the example polishing system, the polishing pad includes an abrasive containing surface.

In some implementations of the example polishing system, the polishing system includes an electrochemical mechanical polishing (ECMP) system.

In some implementations of the example polishing system, the semiconductor workpiece includes silicon carbide (SiC).

In some implementations of the example polishing system, the anion includes a chloride, nitrate, or fluoride anion.

In some implementations of the example polishing system, abrasive particles constitute from about 0.01 wt. % to about 5 wt. % of the slurry.

In some implementations of the example polishing system, the ionic compound constitutes from about 1 wt. % to about 2 wt. % of the slurry.

In some implementations of the example polishing system, the slurry further includes a surfactant.

In some implementations of the example polishing system, the surfactant is a cationic surfactant, an anionic surfactant, or a zwitterionic surfactant.

In some implementations of the example polishing system, the slurry further includes a salt.

In some implementations of the example polishing system, the salt includes NaCl, NaNO₃, NaF, KCl, KNO₃, KF, NH₄Cl, NH₄NO₃, NH₄F, or a combination thereof.

In some implementations of the example polishing system, the slurry is free of permanganate compounds.

In an aspect, the present disclosure provides an example method. In some implementations, the example method includes providing the surface of the semiconductor workpiece on a polishing pad. In some implementations, the example method includes providing a slurry onto a surface of the polishing pad. In some implementations, the example method includes providing a bias between the semiconductor workpiece and the slurry, wherein the slurry includes a solvent and an ionic compound comprising a cation and an anion, wherein one or more of the cation or anion is bonded to an abrasive particle within the slurry.

In some implementations of the example method, the slurry provided to the surface of the polishing pad includes the abrasive particle.

The some implementations the method includes imparting relative motion between the polishing pad and the workpiece.

In some implementations of the example method, the workpiece includes silicon carbide.

In some implementations of the example method, the polishing pad includes an abrasive containing surface.

In some implementations of the example method, the abrasive particle is removed from the polishing pad and into the slurry during polishing.

In some implementations of the example method, the abrasive particle includes i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide, or a combination thereof.

In some implementations of the example method, the metal oxide includes alumina, ceria, zirconia, silica, or a combination thereof.

In some implementations of the example method, the solvent includes an organic solvent.

In some implementations of the example method, the solvent includes water.

In some implementations of the example method, the cation includes an aromatic ring.

In some implementations of the example method, the cation includes a nitrogen-containing cation.

In some implementations of the example method, the nitrogen containing cation includes a pyridinium, quinolinium, or bipyridinium cation.

In some implementations of the example method, the nitrogen-containing cation includes an imidazolium, benzimidazolium, triazolium, thiazolium, or oxazolium cation.

In some implementations of the example method, the nitrogen-containing cation includes a quaternary ammonium cation.

In some implementations of the example method, the quaternary ammonium cation includes a benzyl trialkylammonium cation.

In some implementations of the example method, the nitrogen containing cation includes a diazonium cation.

In some implementations of the example method, the diazonium cation includes a benzyl diazonium cation.

In some implementations of the example method, the cation includes an oxonium cation.

In some implementations of the example method, the oxonium cation includes a pyrylium or benzopyrylium cation.

In some implementations of the example method, the cation includes a phosphonium cation.

In some implementations of the example method, the phosphonium cation includes a benzyl phosphonium cation.

In some implementations of the example method, the cation includes a sulfonium cation.

In some implementations of the example method, the sulfonium cation includes a benzyl sulfonium cation.

In some implementations of the example method, the anion includes a chloride, nitrate, or fluoride anion.

In some implementations of the example method, the cation includes a ferrocenium cation.

In some implementations of the example method, the ionic compound includes an ionic liquid.

In some implementations of the example method, the cation includes a first functional group bonded to the abrasive particle.

In some implementations of the example method, the first functional group includes a silyl group or a hydroxyl group.

In some implementations of the example method, the cation includes a second functional group.

In some implementations of the example method, the second functional group includes an alkyl group, an aryl group, an ether group, a hydroxyl group, or a carboxylic acid group.

In some implementations of the example method, the pH of the slurry is from about 2 to about 10.

In some implementations of the example method, abrasive particles constitute from about 0.01 wt. % to about 5 wt. % of the slurry.

In some implementations of the example method, the ionic compound constitutes from about 1 wt. % to about 2 wt. % of the slurry.

In some implementations of the example method, the slurry further includes a surfactant.

In some implementations of the example method, the surfactant is a cationic surfactant, an anionic surfactant, or a zwitterionic surfactant.

In some implementations of the example method, the slurry further includes a salt.

In some implementations of the example method, the salt includes NaCl, NaNO3, NaF, KCl, KNO3, KF, NH4Cl, NH4NO3, NH4F, or a combination thereof.

In some implementations of the example method, the slurry is free of permanganate compounds.

In some implementations of the example method, the slurry further includes a basic compound.

In some implementations of the example method, the basic compound includes KOH.

In an aspect, the present disclosure provides an example method. In some implementations, the example method includes providing the surface of the semiconductor workpiece on a polishing pad. In some implementations, the example method includes providing a slurry onto a surface of the polishing pad. In some implementations, the example method includes providing a bias between the semiconductor workpiece and the slurry, wherein the slurry includes a solvent, a cationic abrasive particle, and an anion.

The some implementations, the method includes imparting relative motion between the polishing pad and the workpiece.

In some implementations of the example method, the workpiece includes silicon carbide.

In some implementations of the example method, the cationic abrasive particle includes i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide, or a combination thereof.

In some implementations of the example method, the metal oxide includes alumina, ceria, zirconia, silica, or a combination thereof.

In some implementations of the example method, the pH of the slurry is from about 2 to about 10.

In some implementations of the example method, the semiconductor workpiece includes silicon carbide (SiC).

In some implementations of the example method, the anion includes a chloride, nitrate, or fluoride anion.

In some implementations of the example method, abrasive particles constitute from about 0.01 wt. % to about 5 wt. % of the slurry.

In some implementations of the example method, the ionic compound constitutes from about 1 wt. % to about 2 wt. % of the slurry.

In some implementations of the example method, the slurry further includes a surfactant.

In some implementations of the example method, the surfactant is a cationic surfactant, an anionic surfactant, or a zwitterionic surfactant.

In some implementations of the example method, the slurry further includes a salt.

In some implementations of the example method, the salt includes NaCl, NaNO3, NaF, KCl, KNO3, KF, NH4Cl, NH4NO3, NH4F, or a combination thereof.

In some implementations of the example method, the slurry is free of permanganate compounds.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method for polishing a surface of a semiconductor workpiece, the method comprising:
providing the surface of the semiconductor workpiece on a polishing pad;
providing a slurry onto a surface of the polishing pad; and
providing a bias between the semiconductor workpiece and the slurry, wherein the slurry comprises a solvent and an ionic compound comprising a cation and an anion, wherein one or more of the cation or anion is bonded to an abrasive particle within the slurry.

2. The method of claim 1, wherein the slurry provided to the surface of the polishing pad comprises the abrasive particle.

3. The method of claim 1, further comprising imparting relative motion between the polishing pad and the workpiece.

4. The method of claim 1, wherein the workpiece comprises silicon carbide.

5. The method of claim 1, wherein the polishing pad comprises an abrasive containing surface.

6. The method of claim 5, wherein the abrasive particle is removed from the polishing pad and into the slurry during polishing.

7. The method of claim 1, wherein the abrasive particle comprises i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide, or a combination thereof.

8. The method of claim 1, wherein the solvent comprises water.

9. The method of claim 1, wherein the cation comprises an aromatic ring.

10. The method of claim 1, wherein the cation comprises a nitrogen-containing cation.

11. The method of claim 1, wherein the cation comprises an oxonium cation.

12. The method of claim 1, wherein the cation comprises a phosphonium cation.

13. The method of claim 1, wherein the cation comprises a sulfonium cation.

14. The method of claim 1, wherein the anion comprises a chloride, nitrate, or fluoride anion.

15. The method of claim 1, wherein the cation comprises a ferrocenium cation.

16. The method of claim 1, wherein the cation comprises a first functional group bonded to the abrasive particle.

17. The method of claim 16, wherein the cation comprises a second functional group.

18. The method of claim 1, wherein abrasive particles constitute from about 0.01 wt. % to about 5 wt. % of the slurry and the ionic compound constitutes from about 1 wt. % to about 2 wt. % of the slurry.

19. A polishing system for a semiconductor workpiece, comprising:
a platen operable to rotate about an axis;
a polishing pad on the platen;
a bias source;
a workpiece carrier operable to bring the semiconductor workpiece into contact with the polishing pad; and
a slurry comprising a solvent, an abrasive particle, and an ionic compound comprising a cation and an anion, wherein one or more of the cation or anion is bonded to the abrasive particle.

20. A polishing system for a semiconductor workpiece, comprising:
a platen operable to rotate about an axis;
a polishing pad on the platen;
a bias source;
a workpiece carrier operable to bring the semiconductor workpiece into contact with the polishing pad; and
a slurry comprising a solvent, a cationic abrasive particle, and an anion.
